(19) United States
(12) Patent Application Publication
(10) Pub. No.: US 2025/0370353 A1
(43) Pub. Date: Dec. 4, 2025

(54) ENHANCED RUN-TO-RUN PROCESS CONTROL MODELING PLATFORM

(71) Applicant: Applied Materials, Inc., Santa Clara, CA (US)

(72) Inventors: Sivakumar Dhandapani, San Jose, CA (US); Pratik Champalal Kotcher, Chantilly, VA (US); Steven Chen, Santa Clara, CA (US); Mark McTaggart Wylie, Meridian, ID (US); Michael Wanebo, Santa Clara, CA (US)

(21) Appl. No.: 19/221,343

(22) Filed: May 28, 2025

Related U.S. Application Data
(60) Provisional application No. 63/654,831, filed on May 31, 2024.

(51) Int. Cl. G03F 7/00

(52) U.S. Cl. CPC G03F 7/706831; G03F 7/706837; G03F 7/706841

(57) ABSTRACT

A method includes a run-to-run controller to obtain metrology data. The run-to-run controller is associated with a process chamber. The metrology data is of a first substrate. The first substrate has been processed in the process chamber in accordance with a processing operation. The run-to-run controller includes a first model, configured to determine a relationship between substrate metrology and one or more process knob inputs. The run-to-run controller includes a second model, which is configured to recommend one or more corrective actions based on output generated by the first model. The method further includes processing the metrology data by the first model to determine a relationship between the metrology data of the substrate and process knobs of the first processing operation. The method further includes determining, by the second model, a recommended one or more process recipe updates. The method further includes updating a recipe of the processing operation.

### RELATED APPLICATIONS

This application claims the benefit of U.S. Provisional Patent Application No. 63/654,831, filed May 31, 2024, entitled “ENHANCED RUN-TO-RUN PROCESS CONTROL MODELING PLATFORM,” which is incorporated by reference herein.

### TECHNICAL FIELD

The present disclosure relates to a platform for control of manufacturing processes, and more specifically to enhanced run-to-run process control modeling platform.

### BACKGROUND

Products may be produced by performing one or more manufacturing processes using manufacturing equipment. For example, semiconductor manufacturing equipment may be used to produce substrates via semiconductor manufacturing processes. Products are to be produced with particular properties, suited for a target application. Product properties may include repeatability, e.g., freedom of products from defects, adherence or products to target properties, etc. Machine learning models are used in various process control and predictive functions associated with manufacturing equipment. Machine learning models are trained using data associated with the manufacturing equipment. Output of machine learning models may be used in optimization of manufacturing processes.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular embodiments of the disclosure or any scope of the claims. Its sole purpose is to present some concepts of the disclosure in a simplified form as a prelude to the more detailed description that is presented later.

In some aspects of the present disclosure, a method includes a run-to-run controller obtaining metrology data. The run-to-run controller is associated with a process chamber. The metrology data is of a first substrate. The first substrate has been processed in the process chamber in accordance with a processing operation. The run-to-run controller includes a first model, configured to determine a relationship between substrate metrology and one or more process knob inputs. The run-to-run controller includes a second model, which is configured to recommend one or more corrective actions based on the process knob inputs generated by the first model. The second model may be or include a constrained optimizer. The method further includes processing the metrology data by the first model to determine a relationship between the metrology data of the substrate and one or more process knobs of the first processing operation. The method further includes determining, by the second model, a recommended one or more process recipe updates based on the relationship between the metrology data and the one or more process knobs. The method further includes updating a recipe of the processing operation based on the recommended process recipe updates.

In other aspects of the present disclosure, a method includes a run-to-run controller obtaining metrology data of a substrate. The controller is associated with a process chamber. The substrate is associated with the process chamber. The run-to-run controller includes a first model configured to determine a relationship between substrate metrology and one or more process knob inputs. The run-to-run controller includes a second model configured to recommend adjustments to a process chamber digital twin feedback model based on the relationship determined by the first model. The method further includes providing output from the run-to-run controller based on the first metrology data of the first substrate to the process chamber digital twin feedback model. The process chamber digital twin feedback model is configured to adjust operation of a process chamber based on sensor data of the process chamber. The method further includes updating control parameters of the process chamber digital twin feedback model based on the output from the run-to-run controller.

In other aspects of the present disclosure, a non-transitory machine-readable storage medium stores instructions which, when executed, cause a processing device to execute a method including a run-to-run controller obtaining metrology data. The run-to-run controller is associated with a process chamber. The metrology data is of a first substrate. The first substrate has been processed in the process chamber in accordance with a processing operation. The run-to-run controller includes a first model, configured to determine a relationship between substrate metrology and one or more process knob inputs. The run-to-run controller includes a second model, which is configured to recommend one or more corrective actions based on the process knob inputs generated by the first model. The second model may be or include a constrained optimizer. The method further includes processing the metrology data by the first model to determine a relationship between the metrology data of the substrate and one or more process knobs of the first processing operation. The method further includes determining, by the second model, a recommended one or more process recipe updates based on the relationship between the metrology data and the one or more process knobs. The method further includes updating a recipe of the processing operation based on the recommended process recipe updates.

### BRIEF DESCRIPTION OF THE DRAWINGS

The present disclosure is illustrated by way of example, and not by way of limitation in the figures of the accompanying drawings.

FIG. 1 is a block diagram illustrating an exemplary system (exemplary system architecture), according to some embodiments.

FIG. 2 depicts a block diagram of example data set generator to create data sets for training, testing, validating, calibrating, etc. a model, according to some embodiments.

FIG. 3 is a block diagram illustrating system for generating output data, according to some embodiments.

FIG. 4A is a flow diagram of a method for generating a data set for a model, according to some embodiments.

FIG. 4B is a flow diagram of a method for utilizing enhanced process control operations for improving process operations, according to some embodiments.

FIG. 4C is a flow diagram of a method for utilizing a run-to-run controller to update a process operation control module, according to some embodiments.

FIG. 5A depicts a block diagram of a work flow for execution of an enhanced process control platform, according to some embodiments.

FIG. 5B is a block diagram of a work flow for operation of an enhanced process control platform, including a disturbance model, according to some embodiments.

FIG. 5C is a block diagram of a work flow for operation of a run-to-run controller interacting with another control loop for control of manufacturing equipment, according to some embodiments.

FIG. 6 is a block diagram illustrating a computer system 600, according to some embodiments.

### DETAILED DESCRIPTION

Described herein are technologies related to model-integrated control platforms for substrate processing equipment. Manufacturing equipment is used to produce products, such as substrates (e.g., wafers, semiconductors). Manufacturing equipment may include a manufacturing or process chamber to separate the substrate from the environment. The properties of produced substrates are to meet target values to facilitate specific functionalities. Manufacturing parameters are selected to produce substrates that meet the target property values. Many manufacturing parameters (e.g., hardware parameters, process parameters, etc.) contribute to the properties of processed substrates. Manufacturing systems may control parameters by specifying a set point for a property value and receiving data from sensors disposed within the manufacturing chamber, and making adjustments to the manufacturing equipment until the sensor readings match the set point. In some embodiments, trained machine learning models are utilized to improve performance of manufacturing equipment.

In some systems, a control system is implemented to adjust processing conditions for substrate processing operations. Often, adjustments to a process recipe may be performed between process operations or steps and/or between process runs, e.g., before a substrate is provided to a process chamber. Adjustments to a process operation may be based on sensor data obtained from the process chamber. Adjustments to the process operation may be based on one or more measurements of the substrate. Adjustments to the process operation may be based on contextual data, e.g., estimates of chamber aging or drift, component health, etc.

In some systems, a control system includes a model (e.g., a constrained optimizer) that receives a set of conditions and/or measurements, and is configured to generate process condition updates in accordance with a set of constraints. This system may be in place for any process of interest, e.g., targeting a particular product design, operations performed in different chambers (e.g., etch chambers, deposition chambers, etc.), in association with one or more process tools (e.g., a mainframe including several process chambers), chambers, chamber models/designs, combinations of hardware components, or the like. In some systems, operations of the control system may include a rule-based system, a single input/single output (SISO) system, a multiple input/multiple output (MIMO) optimizer system, or the like.

Conventional control systems may suffer from lack of agility and adaptability. In some embodiments, as various process conditions change, adjustment of one or more process variables may cause a different (e.g., greater or lesser) change to target on-wafer metrics than predicted. Further, conventional metrology-based control systems may include metrology from external metrology systems (e.g., standalone metrology facilities), which may only be provided infrequently, making wafer-to-wafer or other high-frequency adjustments inconvenient, costly, or impossible to perform.

Conventional control systems may be improved and/or augmented by the addition or replacement of one or more components with trained machine learning models, as described in embodiments herein. Performing operations of control with trained machine learning models may provide additional functionality in a control scheme, e.g., by adjusting operations of a pre-existing controller to account for data processed by a trained machine learning model. Performing operations of control with a trained machine learning model may provide additional flexibility and/or robustness to a control scheme, e.g., by enabling control to be performed without relying only on a set of pre-defined constraints, but enabling the trained model to make recommendations in novel or unanticipated cases based on trained experience. Performing operations of control with a trained machine learning model may enable linking of one or more tuning parameters to uncertainty of the model, which may provide a significant advantage in robustness compared to a system wherein one or more measurements, which may have independent problems, are to be taken by a control module as the ground truth, resulting in erroneous process condition changes, process recipe updates, errors, or the like.

Aspects of the present disclosure may address one or more shortcomings of conventional solutions. Aspects of the present disclosure may utilize integrated metrology, e.g., on-board sensing for determining control processes. As an example, one or more sensing operations may be performed in the process chamber, in the process tool adjacent to the process chamber, in the process tool as a substrate is provided to or removed from the process chamber, or the like. This on-board sensing data may be utilized in providing control updates frequently, e.g., with wafer-to-wafer frequency. Utilizing on-board sensing data may enable utilizing data from a small number of substrates, e.g., utilizing a window approach including using data from a few substrates processed within a window (e.g., a time window) to update controls for a few subsequent substrates. Utilizing on-board sensing data may enable utilizing data from one or more lots of substrates (e.g., a lot of a target number of substrates associated with a batch of substrate processing, a consecutive batch of substrates, about 25 substrates, or the like) to adjust control of one or more lots of substrates.

Aspects of the present disclosure may enable utilizing frequent measurements to adjust process operations. For example, frequent on-board metrology may be performed. In some cases, every substrate may be measured, such as while entering and/or leaving a process chamber, etc. Rather than relying on infrequent metrology measurements, which may not be timely, may be prone to outlier effects, or the like, utilizing frequent on-board metrology may enable changes occurring on a relatively short time scale to be captured and corrected for improved consistency, yield, and/or properties of produced substrates.

An enhanced process control platform in accordance with the present disclosure may include a virtual metrology model. The virtual metrology model may be a trained machine learning model. The virtual metrology model may receive data indicative of substrate processing, and generate predictions of properties of a substrate. The virtual metrology model may receive data from processing equipment (e.g., sensors of processing equipment), control modules (e.g., process recipe data), external sources (e.g., metrology reference data), etc. The virtual metrology model may receive data that may be used as a proxy for metrology data, data that may be used to calculate metrology data, or the like. The virtual metrology model may, for example, receive optical spectral data of the substrate from an on-board sensing module (e.g., a sensor integrated with a process tool) configured to perform measurements of the substrate while the substrate is within the tool but outside the process chamber, e.g., before or after performance of one or more process operations of interest. The virtual metrology model may make predictions of various substrate properties (e.g., thickness, film thickness, optical properties such as extinction coefficient or index of refraction, electrical properties, critical dimension, feature sidewall angle, etc.) based on the input on-board sensing data. The virtual metrology model may make predictions of substrate metrology in further view of additional input data, such as reference metrology (e.g., metrology of one or more substrates, target metrology, etc.), unit process data (e.g., process recipe data), or the like.

An enhanced process control platform may include a run-to-run controller, which may include an input/output model and a constrained optimizer model. The input/output model may be or include a physics-based model, a machine learning model, or the like. The input/output model may obtain data indicative of process operation output (e.g., substrate metrology data) and generate process operation inputs (e.g., process knobs) that are predicted to have a relationship to the process operation outputs. The input/output model may determine a relationship between process outputs (e.g., metrology data, virtual metrology data, or the like) and process inputs (e.g., process knobs, process set points, or the like). Relationships may be predicted in the vicinity of a current processing condition in process space, e.g., the input/output model may provide a detailed prediction of predicted effects of adjustments to one or more process variables near the previously used set of process conditions. The input/output model may provide a model output indicative of a relationship of a number of process variables available for adjustment, e.g., within parameters of the process operation, process variables designated as adjustable, process variables designated as low-risk to update, or the like.

The run-to-run controller may provide model output from the input/output model (e.g., relationships between process inputs and substrate performance outputs) to a model configured to determine one or more process recipe updates. The second model may be or include an optimizer. The second model may include single input/single output (SISO) functionality, multiple input/multiple output (MIMO) technology, etc. The second model may include one or more constraints. Constraints may be independent, e.g., a maximum or minimum set value allowed by a component, a maximum or minimum reasonable set value related to process engineering, a maximum or minimum set value determined for effects on time efficiency, energy efficiency, material efficiency, environmental impact, or the like, etc. Constraints may be dependent, e.g., a maximum or minimum set value as a function of a second set value of a different property, or further interrelated process constraints. The second model may be a constrained optimizer. The second model may receive target data, e.g., one or more target substrate metrics to be targeted by adjusting process conditions, such as a target critical dimension, target sidewall angle, target substrate thickness, or other target values of substrate properties. The second model may receive a cost function for performing optimization operations. In some embodiments, output of the input/output model may adjust operations of the second model, e.g., by adjusting one or more parameters of the cost function. The input/output model may output one or more metrics of uncertainty, which may be used to modify operations and/or output of the second model. High uncertainty of the input/output model may reduce a period of time of predictions of the second model, a period of time related to a duration to enact one or more process updates, parameters or coefficients of the cost function to reduce weight given to less certain outcomes, dampening control response of uncertain relationships, or the like. Output of the second model may include updates to one or more process operations (e.g., corrective actions) which may be provided to a process tool, a controller, a synergistic control loop, or the like.

In some embodiments, disturbances may further be taken into account in an enhanced process control platform. Disturbances may include alterations in incoming substrates, differences in upstream processing, drift or aging of components involved in upstream processing, or the like. A disturbance model may provide output to the run-to-run controller. The disturbance model may provide output to the input/output model of the run-to-run controller. The disturbance model may be a trained machine learning model. The disturbance model may adjust operations of the input/output model and/or run-to-run controller based on the disturbance data.

In some embodiments, the run-to-run controller may feed data into a process control system, such as a digital twin controller. The process control system may be a pre-existing system, with the run-to-run controller acting to augment or improve operations of the process control system. Two process control loops may interact to improve process control. For example, a process control system may receive data from tool sensors (e.g., trace data indicating process conditions in a process chamber) and provide updates to process parameters based on the tool data. In a separate process, metrology data (e.g., virtual metrology from on-board sensing, external metrology from a standalone metrology facility, etc.) may be provided to a run-to-run controller. Output of the run-to-run controller may be provided to the process control system, which may update operations of the process control system to account for drift, aging, or other changes to the substrate processing procedure, process chamber, or the like.

In some embodiments, a run-to-run controller of an enhanced process control platform may provide updates to process parameters at a frequency that is not provided by other control schemes. For example, an enhanced process control platform may include a run-to-run controller, which may be capable of providing feedback on one or more time scales to fit needs of the processing system. A “run” may be of various lengths. A run may be of customizable length. In some embodiments, a run may be a single process operation, e.g., wafer-to-wafer control may be provided in a semiconductor processing system. In some embodiments, a run may be defined to include some number of substrates, e.g., a string of 5, 10, 20, 50, or any other target number of substrates. Data collected from any target number of substrates may be used to effect change on any target number of future process operations, e.g., to improve robustness of the enhanced process control platform to outliers. A run may be defined to include a pre-defined processing set, e.g., a lot of substrates (for example, a collection of substrates that are processed together, loaded into a process tool together, or the like). A run may include a number of sets, e.g., a few lots. In some embodiments, the run-to-run controller may operate in tandem with one or more other control schemes, updating parameters at a different frequency to account, for example, for drift from different sources. In some embodiments, a digital twin or other process control system may work at a first frequency (e.g., some frequency in relationship to a number of substrates processed). A run-to-run controller may work at a second frequency (e.g., less frequently) to update parameters of the process control system (e.g., digital twin control system) to improve operations of the process control system over a longer period of time. In this way, one system (e.g., the digital twin control system) may operated based on frequently available data (e.g., tool sensor data), and the run-to-run controller may operate on data available less frequently (e.g., external metrology data).

Aspects of the present disclosure provide technological advantages over conventional methods. In some embodiments, application of an input/output model may be integrated with existing control architecture. For example, an input/output model may be used to adjust relationships between process inputs and metrology outputs used by a constrained optimizer to perform process stability control, and may improve operations of the process control system without the introduction of a fully new integrated control system. Operations of the present disclosure may be agnostic to the particular process of interest, e.g., one or more models configured appropriately for the target process operation may be utilized to augment a pre-existing control workflow.

In some systems, corrections to a process system (e.g., process recipe updates) that are based on metrology may include a delay, e.g., in waiting for external or standalone metrology operations to be performed. Further, external metrology may be expensive, in terms of equipment cost, time cost, technician time, material cost, etc. Corrections to the process system in accordance with the present disclosure may be performed based on on-board sensing, virtual metrology, etc., which may provide an advantage in time and cost compared to external metrology, and an advantage in terms of frequency of updates and agility of control. Further, corrections based on virtual metrology may provide increased precision, accuracy, and/or predictive power than process operation corrections based solely on other measurable factors, such as chamber sensor data.

In some aspects of the present disclosure, a method includes a run-to-run controller obtaining metrology data. The run-to-run controller is associated with a process chamber. The metrology data is of a first substrate. The first substrate has been processed in the process chamber in accordance with a processing operation. The run-to-run controller includes a first model, configured to determine a relationship between substrate metrology and one or more process knob inputs. The run-to-run controller includes a second model, which is configured to recommend one or more corrective actions based on the process knob inputs generated by the first model. The second model may be or include a constrained optimizer. The method further includes processing the metrology data by the first model to determine a relationship between the metrology data of the substrate and one or more process knobs of the first processing operation. The method further includes determining, by the second model, a recommended one or more process recipe updates based on the relationship between the metrology data and the one or more process knobs. The method further includes updating a recipe of the processing operation based on the recommended process recipe updates.

In other aspects of the present disclosure, a method includes a run-to-run controller obtaining metrology data of a substrate. The controller is associated with a process chamber. The substrate is associated with the process chamber. The run-to-run controller includes a first model configured to determine a relationship between substrate metrology and one or more process knob inputs. The run-to-run controller includes a second model configured to recommend adjustments to a process chamber digital twin feedback model based on the relationship determined by the first model. The method further includes providing output from the run-to-run controller based on the first metrology data of the first substrate to the process chamber digital twin feedback model. The process chamber digital twin feedback model is configured to adjust operation of a process chamber based on sensor data of the process chamber. The method further includes updating control parameters of the process chamber digital twin feedback model based on the output from the run-to-run controller.

In other aspects of the present disclosure, a non-transitory machine-readable storage medium stores instructions which, when executed, cause a processing device to execute a method including a run-to-run controller obtaining metrology data. The run-to-run controller is associated with a process chamber. The metrology data is of a first substrate. The first substrate has been processed in the process chamber in accordance with a processing operation. The run-to-run controller includes a first model, configured to determine a relationship between substrate metrology and one or more process knob inputs. The run-to-run controller includes a second model, which is configured to recommend one or more corrective actions based on the process knob inputs generated by the first model. The second model may be or include a constrained optimizer. The method further includes processing the metrology data by the first model to determine a relationship between the metrology data of the substrate and one or more process knobs of the first processing operation. The method further includes determining, by the second model, a recommended one or more process recipe updates based on the relationship between the metrology data and the one or more process knobs. The method further includes updating a recipe of the processing operation based on the recommended process recipe updates.

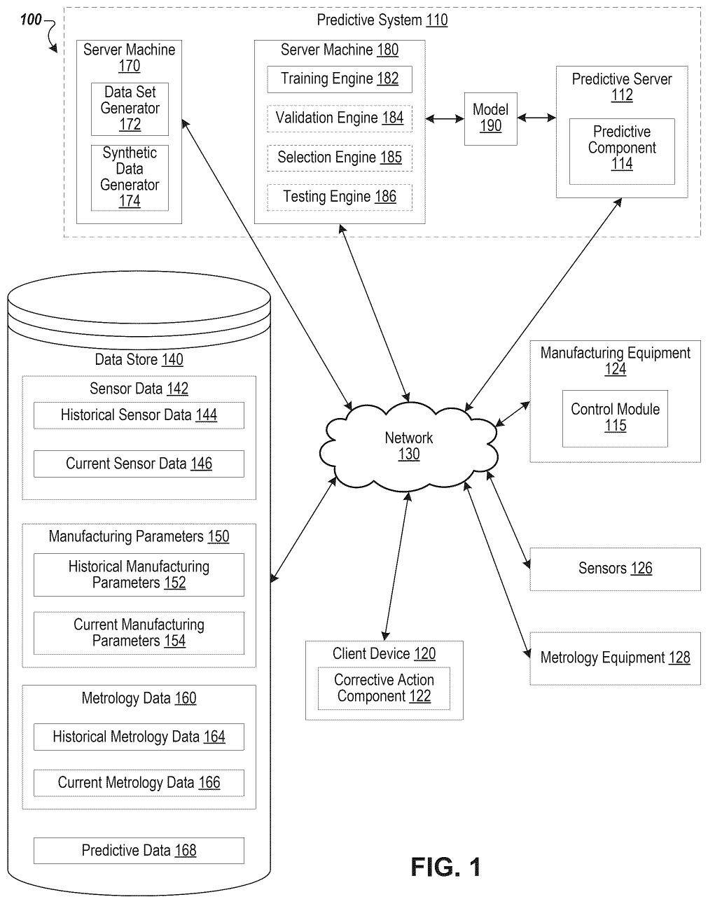

FIG. 1 is a block diagram illustrating an exemplary system 100 (exemplary system architecture), according to some embodiments. The system 100 includes a client device 120, manufacturing equipment 124, metrology equipment 128, predictive server 112, and data store 140. The predictive server 112 may be part of predictive system 110. Predictive system 110 may further include server machines 170 and 180.

Manufacturing equipment 124 may include one or more process tools, process chambers, or the like for performing processing operations to manufacture substrates. Substrates may have property values (film thickness, film strain, etc.) measured by metrology equipment 128. Metrology data 160 may be a component of data store 140. Metrology data 160 may include historical metrology data (e.g., metrology data associated with previously processed products). In some embodiments, historical metrology data may be used in training a machine leaning model, in calibrating a physics-based model, in generating a reduced-order model, or the like. Historical metrology data may be utilized in determining a historical likelihood of developing substrate defects, and the historical likelihood may be utilized in generating a machine learning model, in calibrating a physics-based model, in determining whether to use a model in association with a process of interest, or the like.

Metrology data 160 may be provided by instruments separate from a manufacturing mainframe, e.g., substrates may be measured at a standalone metrology facility. In some embodiments, metrology data 160 may be provided without use of a standalone metrology facility, e.g., in-situ metrology data (e.g., metrology or a proxy for metrology collected during processing), integrated metrology data (e.g., metrology or a proxy for metrology collected while a product is within a chamber or under vacuum, but not during processing operations), inline metrology data (e.g., data collected after a substrate is removed from vacuum), etc. Metrology data 160 may include current metrology data (e.g., metrology data associated with a product currently or recently processed). Current metrology data may be provided to update one or more models in association with defect root cause correction, e.g., by updating weights or biases of a machine learning model, updating parameters of a physics-based model, updating coefficients of a reduced order model, or the like. Metrology data 160 may be generated by measuring one or more properties of a substrate that are correlated to properties of interest, and using a model to interpret the measurements to generate virtual metrology. For example, reflectance spectra of substrates may be collected. A model, such as a physics-based or trained machine learning or artificial intelligence model, may be used to determine properties of interest (such as film thickness) from the spectra as virtual metrology.

In some embodiments, manufacturing equipment 124 may include a control module 115. The control module 115 may be an edge computing device, e.g., may be physically located at the site of the manufacturing equipment, at a processing core in or near a manufacturing facility serving multiple sets of manufacturing equipment, or the like. The control module 115 may adjust operations of manufacturing equipment 124 based on analysis of system 100, e.g., based on output of model 190. In some embodiments, one or more operations attributed to predictive system 110 may be performed by control module 115. In some embodiments, control module 115 may be or include a constrained optimizer model, e.g., a model configured to maximize or minimize a target objective function (such as substrate properties of interest) with constraints placed on possible solutions (e.g., maximum or minimum values of process inputs put in place by subject matter experts). In some embodiments, control module 115 may include a multiple input/multiple output (MIMO) constrained optimization model. A MIMO model may optimize the system's performance by adjusting multiple input variables while satisfying constraints and considering influences on multiple output variables (e.g., multiple substrate properties of interest).

Data store 140 may further include manufacturing parameters 150. Manufacturing parameters 150 may include parameters associated with performing substrate processing procedures, such as recipe data (e.g., process parameters), equipment constants (e.g., hardware parameters, parameters determining how operations of manufacturing equipment 124 are performed), indications of installed hardware components, or the like. Manufacturing parameter data, similar to metrology data 160, may include historical parameters 152 and current parameters 154. Historical parameters 152 may be utilized in generating a model (e.g., one or more models 190) for improving process conditions, e.g., to be used to reduce a likelihood of developing a defect during substrate processing or increase a likelihood of achieving target substrate properties. Current parameters 154 may be utilized in determining whether a process of interest is likely to generate a substrate exhibiting target properties, e.g., by providing the current parameters 154 to model 190.

In some embodiments metrology data 160 and/or manufacturing parameters 150 may be processed (e.g., by the client device 120, control module 115, and/or by the predictive server 112). Processing of the data may include generating features. In some embodiments, the features are a pattern in the metrology data 160 and/or manufacturing parameters 150 (e.g., slope, width, height, peak, etc.) or a combination of values from the metrology data and/or manufacturing parameters (e.g., power derived from voltage and current, etc.). Manufacturing parameters 150 and/or metrology data 160 may include features and the features may be used by predictive component 114 for performing signal processing and/or for obtaining predictive data 168 for performance of a corrective action.

Each instance of metrology data 160 and/or manufacturing parameters 150 may correspond to a product, a set of manufacturing equipment, a type of substrate produced by manufacturing equipment, or the like. A model 190 may also be associated with a particular product, substrate design, set of manufacturing equipment, design of manufacturing chamber, or the like. For example, a fluid dynamics model may be generated based on geometry of a type or design of process tool, a reduced order or machine learning model may be generated based on data from a particular design of chamber or a specific specimen of process chamber (e.g., to account for differences between nominally identical chambers), or the like.

Several models may be utilized in connection with a run-to-run process control platform. For example, an artificial intelligence or machine learning model may be used in connection with sensor data and/or on-board substrate sensing to generate virtual metrology data. A physics-based, empirical, or machine learning process model may be used to determine relationships between process inputs (e.g., process knob settings) and process outputs (e.g., virtual or measured metrology), which may change as chamber condition, seasoning, or age changes. A third model may perform constrained optimization based on the relationships defined by the input/output (I/O) model. A fourth model (e.g., a machine learning or artificial intelligence based model) may account for disturbances in processing, e.g., variation between incoming substrates, variations between incoming substrate processing conditions, or the like. The disturbance model may adjust operation of one or more other models, e.g., the I/O model, the optimizer, or the like. A fifth model may perform digital twin process control, e.g., a physics-based or data-based (e.g., artificial intelligence, machine learning) process control model, which may include dynamic parameters that are updated based on a run-to-run controller, e.g., executed by control module 115, including the other types of models described here, or the like.

The data store may further store information associating sets of different data types, e.g. information indicative that a set of sensor data, a set of metrology data, and a set of manufacturing parameters are all associated with the same product, manufacturing equipment, type of substrate, etc.

In some embodiments, a processing device (e.g., via a model) may be used to generate predictive data 168. Predictive data 168 may include one or more indications of predicted improvements to a processing operation (e.g., to improve efficiency, to reduce energy usage or process time, to reduce a likelihood of generating substrate defects, or the like). Predictive data 168 may be utilized by system 100 for performance of a corrective action (e.g., providing alerts to a user, updating process recipes, updating manufacturing parameters, scheduling maintenance, or the like).

In some embodiments, predictive system 110 may generate predictive data 168 utilizing a physics-based model. A physics-based model may include a mathematical representation of the laws of nature at play in the process chamber. The physics-based model may be a first principles model, an approximate model, or the like. The physics-based model may include a representation or parameterization of chamber geometry, pumping parameters, gas flow parameters, or the like. The physics-based model may be a gas flow model, a computational fluid dynamics model, a gas pressure model, or the like. A physics-based model may include one or more parameters that are allowed to be adjusted to fit the physics-based model to data, e.g., historical metrology data 164, e.g., to account for details of physics of the process chamber not captured by the original model parameters.

In some embodiments, predictive system 110 may generate predictive data 168 utilizing a reduced order model. A reduced order model may include a simplified version of a complex model (e.g., a simplified version of a computational fluid dynamics model). The reduced order model may mimic the performance of the full model under a target range of conditions (e.g., relevant to substrate processing conditions), while being more computationally efficient. Training data (e.g., historical metrology data 164, historical parameters 152, etc.) may be utilizing in determining which simplifications from a more complete model to make, in determining coefficients of a reduced order model, or the like.

In some embodiments, predictive system 110 may generate predictive data 168 using supervised machine learning (e.g., predictive data 168 includes output from a machine learning model that was trained using labeled data, such as manufacturing parameter data labelled with metrology data (e.g., which may include rates of defect formation, or other metrology of interest). In some embodiments, predictive system 110 may generate predictive data 168 using unsupervised machine learning (e.g., predictive data 168 includes output from a machine learning model that was trained using unlabeled data, output may include clustering results, principle component analysis, anomaly detection, etc.). In some embodiments, predictive system 110 may generate predictive data 168 using semi-supervised learning (e.g., training data may include a mix of labeled and unlabeled data, etc.).

Client device 120, manufacturing equipment 124, metrology equipment 128, predictive server 112, data store 140, server machine 170, and server machine 180 may be coupled to each other via network 130 for generating predictive data 168 to perform corrective actions. In some embodiments, network 130 may provide access to cloud-based services. Operations performed by client device 120, predictive system 110, data store 140, etc., may be performed by virtual cloud-based devices.

In some embodiments, network 130 is a public network that provides client device 120 with access to the predictive server 112, data store 140, and other publicly available computing devices. In some embodiments, network 130 is a private network that provides client device 120 access to manufacturing equipment 124, metrology equipment 128, data store 140, and other privately available computing devices. Network 130 may include one or more Wide Area Networks (WANs), Local Area Networks (LANs), wired networks (e.g., Ethernet network), wireless networks (e.g., an 802.11 network or a Wi-Fi network), cellular networks (e.g., a Long Term Evolution (LTE) network), routers, hubs, switches, server computers, cloud computing networks, and/or a combination thereof.

Client device 120 may include computing devices such as Personal Computers (PCs), laptops, mobile phones, smart phones, tablet computers, netbook computers, network connected televisions (“smart TV”), network-connected media players (e.g., Blu-ray player), a set-top-box, Over-the-Top (OTT) streaming devices, operator boxes, etc. Client device 120 may include a corrective action component 122. Corrective action component 122 may receive user input (e.g., via a Graphical User Interface (GUI) displayed via the client device 120) of an indication associated with manufacturing equipment 124. In some embodiments, corrective action component 122 transmits the indication to the predictive system 110, receives output (e.g., predictive data 168) from the predictive system 110, determines a corrective action based on the output, and causes the corrective action to be implemented. In some embodiments, corrective action component 122 obtains model input data associated with manufacturing equipment 124 (e.g., from data store 140, etc.) and provides the model input data (e.g., current parameters 154) associated with the manufacturing equipment 124 to predictive system 110.

In some embodiments, corrective action component 122 receives an indication of a corrective action from the predictive system 110 and causes the corrective action to be implemented. Each client device 120 may include an operating system that allows users to one or more of generate, view, or edit data (e.g., indication associated with manufacturing equipment 124, corrective actions associated with manufacturing equipment 124, etc.). In some embodiments, operations attributed to corrective action component 122 may be executed by control module 115, e.g., within a lot of substates, corrective actions including adjusting processing conditions may be performed by control module 115, semi-permanent adjustments to process recipes may be performed by control module 115 and/or corrective action component 122, etc.

In some embodiments, metrology data 160 (e.g., historical metrology data 164) corresponds to historical property data of products (e.g., products processed using manufacturing parameters associated with historical manufacturing parameters 152) and predictive data 168 is associated with predicted property data (e.g., of products to be produced or that have been produced in conditions recorded by current manufacturing parameters 154). Metrology data 160 may include offline metrology (e.g., measured in an external device or facility), online metrology (e.g., measured within a process tool, during processing, between process steps, or the like), virtual metrology, etc.

In some embodiments, predictive data 168 is or includes predicted metrology data (e.g., virtual metrology data, defect generation) of the products to be produced or that have been produced according to conditions recorded as current measurement data and/or current manufacturing parameters. In some embodiments, predictive data 168 is or includes predictions of conditions in a process chamber in connection with current parameters 154 generated in the process chamber. In some embodiments, predictive data 168 is or includes updates to process parameters (e.g., process knobs) predicted to result in target changes to substrate properties, processing performance, process efficiency, or the like. In some embodiments, predictive data 168 is or includes an indication of any abnormalities (e.g., abnormal products, abnormal components, abnormal manufacturing equipment 124, abnormal energy usage, etc.) and optionally one or more causes of the abnormalities. In some embodiments, predictive data 168 is an indication of change over time or drift in some component of manufacturing equipment 124, metrology equipment 128, and the like. In some embodiments, predictive data 168 is an indication of an end of life of a component of manufacturing equipment 124, metrology equipment 128, or the like.

Performing manufacturing processes that result in defective products can be costly in time, energy, products, components, manufacturing equipment 124, the cost of identifying the defects and discarding the defective product, etc. By inputting manufacturing parameters that are being used or are to be used to manufacture a product into predictive system 110, receiving output of predictive data 168, and performing a corrective action based on the predictive data 168, system 100 can have the technical advantage of avoiding the cost of producing, identifying, and discarding defective products.

Performing manufacturing processes that result in failure of the components of the manufacturing equipment 124 can be costly in downtime, damage to products, damage to equipment, express ordering replacement components, etc. By inputting manufacturing parameters that are being used or are to be used to manufacture a product, metrology data, measurement data, etc., receiving output of predictive data 168, and performing corrective action (e.g., predicted operational maintenance, such as replacement, processing, cleaning, etc. of components) based on the predictive data 168, system 100 can have the technical advantage of avoiding the cost of one or more of unexpected component failure, unscheduled downtime, productivity loss, unexpected equipment failure, product scrap, or the like. Monitoring the performance over time of components, e.g. manufacturing equipment 124, metrology equipment 128, and the like, may provide indications of degrading components.

Manufacturing parameters may be suboptimal for producing product which may have costly results of increased resource (e.g., energy, coolant, gases, etc.) consumption, increased amount of time to produce the products, increased component failure, increased amounts of defective products, increased environmental impact, etc. By inputting indications of manufacturing parameters 150 and/or metrology data 160 into a model 190, receiving an output of predictive data 168, and performing a corrective action of updating manufacturing parameters (e.g., setting optimal manufacturing parameters, updating a process recipe, or the like), system 100 can have the technical advantage of using optimal manufacturing parameters (e.g., hardware parameters, process parameters, optimal design) to avoid costly results of suboptimal manufacturing parameters, including reducing a likelihood of developing defects on substrates, maintaining high product throughput while managing a likelihood of developing defects, or the like.

In some embodiments, the corrective action includes providing an alert (e.g., an alarm to stop or not perform the manufacturing process if the predictive data 168 indicates a predicted abnormality, such as an abnormality of the product, a component, or manufacturing equipment 124). In some embodiments, performance of the corrective action includes causing updates to one or more manufacturing parameters. In some embodiments, performance of a corrective action may include recalibration or adjustment of parameters of a physics-based model or reduced order model. In some embodiments performance of a corrective action may include retraining a machine learning model associated with manufacturing equipment 124. In some embodiments, performance of a corrective action may include training a new machine learning model associated with manufacturing equipment 124.

Manufacturing parameters 150 may include hardware parameters (e.g., information indicative of which components are installed in manufacturing equipment 124, indicative of component replacements, indicative of component age, indicative of software version or updates, etc.) and/or process parameters (e.g., temperature, pressure, flow, rate, electrical current, voltage, gas flow, lift speed, etc.). In some embodiments, the corrective action includes causing preventative operative maintenance (e.g., replace, process, clean, etc. components of the manufacturing equipment 124). In some embodiments, the corrective action includes causing design optimization (e.g., updating manufacturing parameters, manufacturing processes, manufacturing equipment 124, etc. for an optimized product). In some embodiments, the corrective action includes updating a recipe (e.g., altering the timing of manufacturing subsystems entering an idle or active mode, altering set points of various property values, etc.).

Predictive server 112, server machine 170, and server machine 180 may each include one or more computing devices such as a rackmount server, a router computer, a server computer, a personal computer, a mainframe computer, a laptop computer, a tablet computer, a desktop computer, Graphics Processing Unit (GPU), accelerator Application-Specific Integrated Circuit (ASIC) (e.g., Tensor Processing Unit (TPU)), etc. Operations of predictive server 112, server machine 170, server machine 180, data store 140, etc., may be performed by a cloud computing service, cloud data storage service, etc. Operations of control module 115 may be performed by a similar device, a control unit or control processor integrated with manufacturing equipment 124, or the like.

Predictive server 112 may include a predictive component 114. In some embodiments, the predictive component 114 may receive current manufacturing parameters 154 (e.g., receive from the client device 120, retrieve from the data store 140) and generate output (e.g., predictive data 168) for performing corrective action associated with the manufacturing equipment 124 based on the current data. In some embodiments, predictive data 168 may include virtual metrology. Predictive data 168 may include input/output mappings (e.g., process knob/substrate property mappings). Predictive data 168 may include disturbance data, e.g., updates to one or more parameters of a model or controller based on disturbances in incoming substrates, conditions, or the like. Predictive data 168 may include updates to a process (e.g., a process in progress) based on a digital twin model. In some embodiments, predictive component 114 may use one or more trained machine learning models 190 to determine the output for performing the corrective action based on current data.

Manufacturing equipment 124 may be associated with one or more models, e.g., model 190. In some embodiments, model(s) 190 may be or include physics-based models, reduced order models, machine learning models, etc. Machine learning models associated with manufacturing equipment 124 may perform many tasks, including process control, classification, performance predictions, etc. Model 190 may be trained using data associated with manufacturing equipment 124 or products processed by manufacturing equipment 124, e.g., sensor data 142, manufacturing parameters 150 (e.g., associated with process control of manufacturing equipment 124), metrology data 160 (e.g., generated by metrology equipment 128), etc.

One type of machine learning model that may be used to perform some or all of the above tasks is an artificial neural network, such as a deep neural network. Artificial neural networks generally include a feature representation component with a classifier or regression layers that map features to a desired output space. A convolutional neural network (CNN), for example, hosts multiple layers of convolutional filters. Pooling is performed, and non-linearities may be addressed, at lower layers, on top of which a multi-layer perceptron is commonly appended, mapping top layer features extracted by the convolutional layers to decisions (e.g. classification outputs).

A recurrent neural network (RNN) is another type of machine learning model. A recurrent neural network model is designed to interpret a series of inputs where inputs are intrinsically related to one another, e.g., time trace data, sequential data, etc. Output of a perceptron of an RNN is fed back into the perceptron as input, to generate the next output.

Deep learning is a class of machine learning algorithms that use a cascade of multiple layers of nonlinear processing units for feature extraction and transformation. Each successive layer uses the output from the previous layer as input. Deep neural networks may learn in a supervised (e.g., classification) and/or unsupervised (e.g., pattern analysis) manner. Deep neural networks include a hierarchy of layers, where the different layers learn different levels of representations that correspond to different levels of abstraction. In deep learning, each level learns to transform its input data into a slightly more abstract and composite representation. In an image recognition application, for example, the raw input may be a matrix of pixels; the first representational layer may abstract the pixels and encode edges; the second layer may compose and encode arrangements of edges; the third layer may encode higher level shapes (e.g., teeth, lips, gums, etc.); and the fourth layer may recognize a scanning role. Notably, a deep learning process can learn which features to optimally place in which level on its own. The “deep” in “deep learning” refers to the number of layers through which the data is transformed. More precisely, deep learning systems have a substantial credit assignment path (CAP) depth. The CAP is the chain of transformations from input to output. CAPs describe potentially causal connections between input and output. For a feedforward neural network, the depth of the CAPs may be that of the network and may be the number of hidden layers plus one. For recurrent neural networks, in which a signal may propagate through a layer more than once, the CAP depth is potentially unlimited.

In some embodiments, predictive component 114 obtains current metrology data 166 and/or current manufacturing parameters 154, performs signal processing to break down the current data into sets of current data, provides the sets of current data as input to a trained model 190, and obtains outputs indicative of predictive data 168 from the trained model 190. In some embodiments, predictive component 114 receives metrology data (e.g., predicted defect formation likelihood) of a substrate and provides the metrology data to trained model 190. Model 190 may be configured to accept data indicative of manufacturing parameters and generate as output defect formation data. In some embodiments, predictive data is indicative of metrology data (e.g., prediction of substrate quality, substate defect likelihood, or the like). In some embodiments, predictive data is indicative of manufacturing equipment health (e.g., an indication of a component or components likely to be contributing to substrate defects).

In some embodiments, the various models discussed in connection with model 190 (e.g., supervised machine learning model, unsupervised machine learning model, etc.) may be combined in one model (e.g., an ensemble model), or may be separate models.

Data store 140 may be a memory (e.g., random access memory), a drive (e.g., a hard drive, a flash drive), a database system, a cloud-accessible memory system, or another type of component or device capable of storing data. Data store 140 may include multiple storage components (e.g., multiple drives or multiple databases) that may span multiple computing devices (e.g., multiple server computers). The data store 140 may store manufacturing parameters 150, metrology data 160, and predictive data 168.

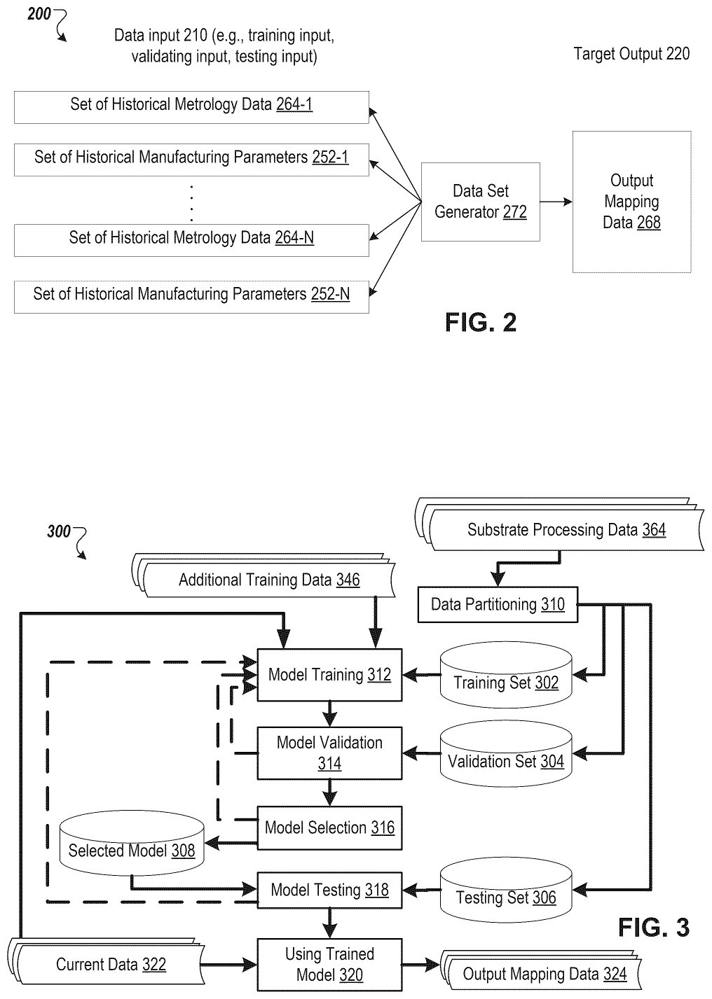

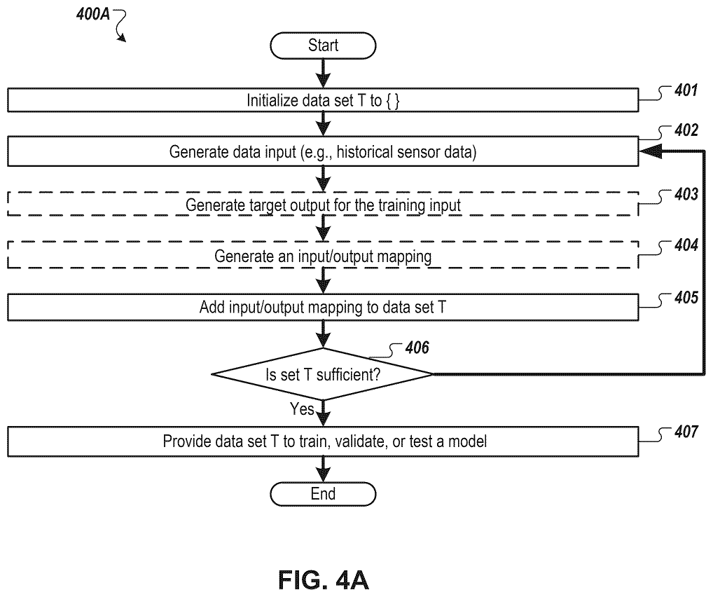

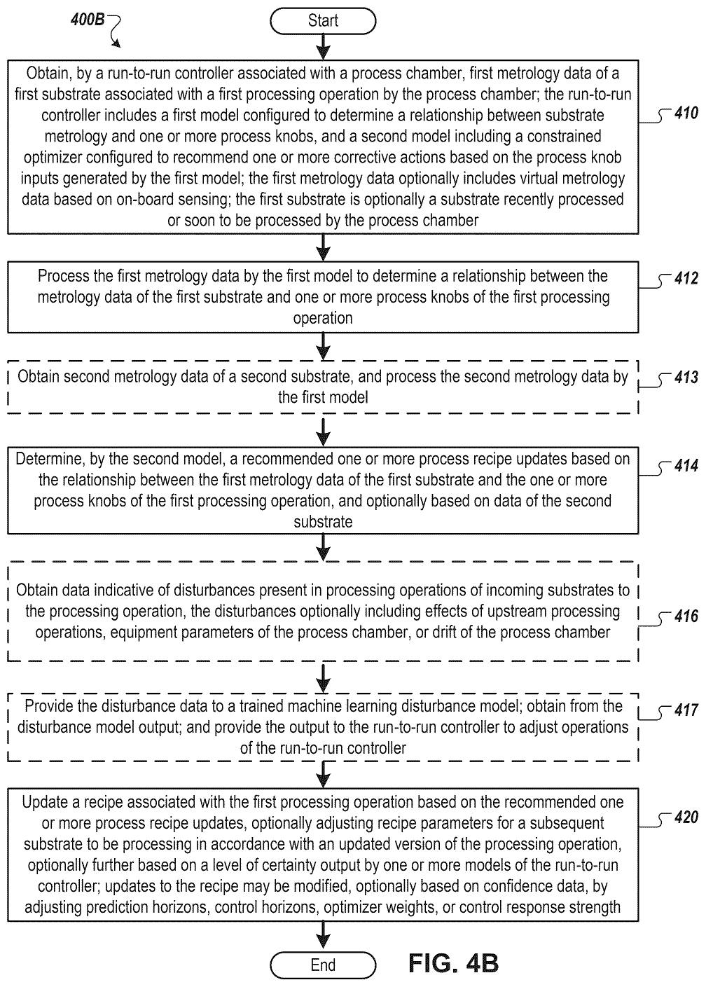

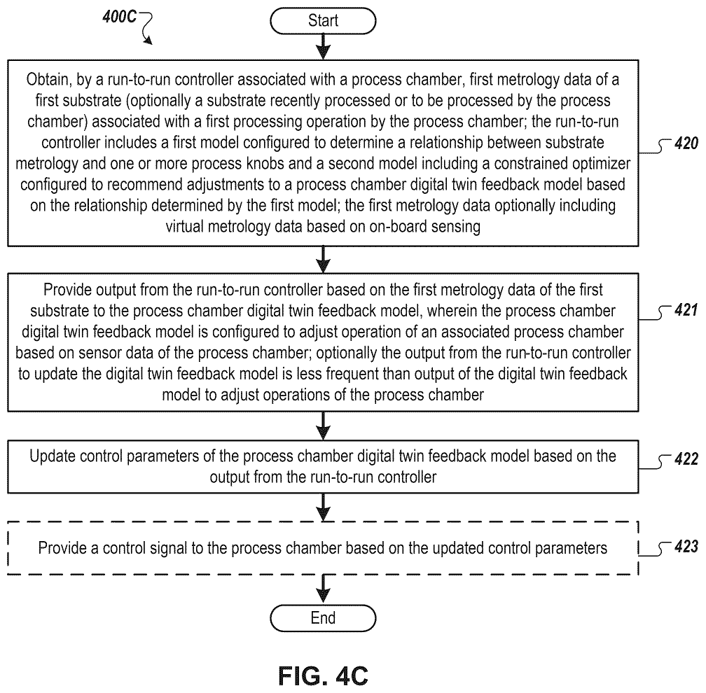

In some embodiments, predictive system 110 further includes server machine 170 and server machine 180. Server machine 170 includes a data set generator 172 that is capable of generating data sets (e.g., a set of data inputs and a set of target outputs) to train, validate, and/or test model(s) 190, including one or more machine learning models. Some operations of data set generator 172 are described in detail below with respect to FIGS. 2 and 4A. In some embodiments, data set generator 172 may partition the historical data (e.g., historical manufacturing parameters 152, historical metrology data 164) into a training set (e.g., sixty percent of the historical data), a validating set (e.g., twenty percent of the historical data), and a testing set (e.g., twenty percent of the historical data).

Server machine 180 includes a training engine 182, a validation engine 184, selection engine 185, and/or a testing engine 186. An engine (e.g., training engine 182, a validation engine 184, selection engine 185, and a testing engine 186) may refer to hardware (e.g., circuitry, dedicated logic, programmable logic, microcode, processing device, etc.), software (such as instructions run on a processing device, a general purpose computer system, or a dedicated machine), firmware, microcode, or a combination thereof. The training engine 182 may be capable of training a model 190 using one or more sets of features associated with the training set from data set generator 172. The training engine 182 may generate multiple trained models 190, where each trained model 190 corresponds to a distinct set of features of the training set. For example, a first trained model may have been trained using all features (e.g., X1-X5), a second trained model may have been trained using a first subset of the features (e.g., X1, X2, X4), and a third trained model may have been trained using a second subset of the features (e.g., X1, X3, X4, and X5) that may partially overlap the first subset of features. Data set generator 172 may receive the output of a trained, collect that data into training, validation, and testing data sets, and use the data sets to train a second model (e.g., a machine learning model configured to output predictive data, corrective actions, etc.).

Validation engine 184 may be capable of validating a trained model 190 using a corresponding set of features of the validation set from data set generator 172. For example, a first trained machine learning model 190 that was trained using a first set of features of the training set may be validated using the first set of features of the validation set. The validation engine 184 may determine an accuracy of each of the trained models 190 based on the corresponding sets of features of the validation set. Validation engine 184 may discard trained models 190 that have an accuracy that does not meet a threshold accuracy. In some embodiments, selection engine 185 may be capable of selecting one or more trained models 190 that have an accuracy that meets a threshold accuracy. In some embodiments, selection engine 185 may be capable of selecting the trained model 190 that has the highest accuracy of the trained models 190.

Testing engine 186 may be capable of testing a trained model 190 using a corresponding set of features of a testing set from data set generator 172. For example, a first trained machine learning model 190 that was trained using a first set of features of the training set may be tested using the first set of features of the testing set. Testing engine 186 may determine a trained model 190 that has the highest accuracy of all of the trained models based on the testing sets.

In the case of a machine learning model, model 190 may refer to the model artifact that is created by training engine 182 using a training set that includes data inputs and corresponding target outputs (correct answers for respective training inputs. Patterns in the data sets can be found that map the data input to the target output (the correct answer), and machine learning model 190 is provided mappings that capture these patterns. The machine learning model 190 may use one or more of Support Vector Machine (SVM), Radial Basis Function (RBF), clustering, supervised machine learning, semi-supervised machine learning, unsupervised machine learning, k-Nearest Neighbor algorithm (k-NN), linear regression, random forest, neural network (e.g., artificial neural network, recurrent neural network), etc. In some embodiments, one or more machine learning models 190 may be trained using historical data (e.g., historical parameters 152).

Predictive component 114 may provide current data to model 190 and may run model 190 on the input to obtain one or more outputs. For example, predictive component 114 may provide current manufacturing parameters 154 to model 190 and may run model 190 on the input to obtain one or more outputs. Predictive component 114 may be capable of determining (e.g., extracting) predictive data 168 from the output of model 190. Predictive component 114 may determine (e.g., extract) confidence data from the output that indicates a level of confidence that predictive data 168 is an accurate predictor of a process associated with the input data for products produced or to be produced using the manufacturing equipment 124 at the current manufacturing parameters. Predictive component 114 or corrective action component 122 may use the confidence data to decide whether to cause a corrective action associated with the manufacturing equipment 124 based on predictive data 168.

The confidence data may include or indicate a level of confidence that the predictive data 168 is an accurate prediction for products or components associated with at least a portion of the input data. In one example, the level of confidence is a real number between 0 and 1 inclusive, where 0 indicates no confidence that the predictive data 168 is an accurate prediction for products processed according to input data or component health of components of manufacturing equipment 124 and 1 indicates absolute confidence that the predictive data 168 accurately predicts properties of products processed according to input data or component health of components of manufacturing equipment 124. Responsive to the confidence data indicating a level of confidence below a threshold level for a predetermined number of instances (e.g., percentage of instances, frequency of instances, total number of instances, etc.) predictive component 114 may cause trained model 190 to be re-trained (e.g., based on current manufacturing parameters, current metrology, measurements of conditions in the chamber, etc.). In some embodiments, retraining may include generating one or more data sets (e.g., via data set generator 172) utilizing historical data.

For purpose of illustration, rather than limitation, aspects of the disclosure describe the training of one or more machine learning models 190 using historical data (e.g., historical metrology data 164, historical manufacturing parameters) and inputting current data (e.g., current manufacturing parameters, and current metrology data) into the one or more trained machine learning models to determine predictive data 168. In other embodiments, a heuristic model, physics-based model, or rule-based model is used to determine predictive data 168 (e.g., without using a trained machine learning model). In some embodiments, such models may be trained using historical data. In some embodiments, these models may be retrained utilizing a historical data and/or current data. Predictive component 114 may monitor historical manufacturing parameters, and metrology data 160. Any of the information described with respect to data inputs 210 of FIG. 2 may be monitored or otherwise used in the heuristic, physics-based, or rule-based model.

In some embodiments, the functions of client device 120, predictive server 112, control module 115, server machine 170, and server machine 180 may be provided by a fewer number of machines. For example, in some embodiments server machines 170 and 180 may be integrated into a single machine, while in some other embodiments, server machine 170, server machine 180, and predictive server 112, and/or control module 115 may be integrated into a single machine. For example, operations of model 190 may be executed by control module 115, while operations of server machine 170 and server machine 180 may be performed by predictive server 112. In some embodiments, client device 120 and predictive server 112 may be integrated into a single machine. In some embodiments, functions of client device 120, predictive server 112, server machine 170, server machine 180, and data store 140 may be performed by a cloud-based service.

In general, functions described in one embodiment as being performed by client device 120, predictive server 112, control module 115, server machine 170, and server machine 180 can also be performed on predictive server 112 in other embodiments, if appropriate. In addition, the functionality attributed to a particular component can be performed by different or multiple components operating together. For example, in some embodiments, the predictive server 112 may determine the corrective action based on the predictive data 168. In another example, client device 120 may determine the predictive data 168 based on output from the trained machine learning model.

In addition, the functions of a particular component can be performed by different or multiple components operating together. One or more of the predictive server 112, server machine 170, or server machine 180 may be accessed as a service provided to other systems or devices through appropriate application programming interfaces (API).

In embodiments, a “user” may be represented as a single individual. However, other embodiments of the disclosure encompass a “user” being an entity controlled by a plurality of users and/or an automated source. For example, a set of individual users federated as a group of administrators may be considered a “user.”

FIG. 2 depicts a block diagram of example data set generator 272 (e.g., data set generator 172 of FIG. 1) to create data sets for training, testing, validating, calibrating, etc. a model (e.g., model 190 of FIG. 1), according to some embodiments. Each data set generator 272 may be part of server machine 170 of FIG. 1. In some embodiments, data set generator 272 may generate data sets to be utilized to adjust, validate, test, or the like a physics-based model or reduced order model. In some embodiments, data set generator 272 may generate data sets to be utilized in generating, validating, etc., machine learning or artificial intelligence models in association with the manufacturing equipment. In some embodiments, several models associated with manufacturing equipment 124 may be trained, used, and maintained (e.g., within a manufacturing facility). One or more physics-based models, one or more reduced order models, and/or one or more trained machine learning models may be generated and maintained in association with the manufacturing equipment. Each model may be associated with one data set generators 272, multiple models may share a data set generator 272, etc.

FIG. 2 depicts a system 200 including data set generator 272 for creating data sets for one or more supervised models (e.g., including data associated with input to a model and output from the model). Data set generator 272 may create data sets (e.g., data input 210, target output 220) using historical data, which may include manufacturing parameters, defect generation likelihood, metrology measurements, or the like. In some embodiments, a data set generator similar to data set generator 272 may be utilized to train an unsupervised model, e.g., target output 220 may not be generated by data set generator 272.

Data set generator 272 may generate data sets to train, test, and validate a model, e.g., a machine learning model. Data set generator 272 may generate data sets to calibrate a model, e.g., a physics-based model (including reduced order models). In some embodiments, data set generator 272 may generate data sets for a machine learning model. In some embodiments, data set generator 272 may generate data sets for training, testing, and/or validating a model configured to be used in an enhanced process control platform, e.g., integrated with a constrained optimizer for improving outcomes of substrate processing operations. Data set generator 272 (or a collection of data set generators including data set generator 272) may be used for training, testing, and/or validating a number of models, each performing a different role in a work flow directed toward operations of an enhanced process control platform.

A model to be generated (e.g., trained, calibrated, or the like) may be provided with a set of historical manufacturing parameters 252-1 and a set of historical metrology data 264-1 as data input 210. The set of historical manufacturing parameters 252-1 may include process control set points. The set of historical manufacturing parameters 252-1 may include parameters determining actions of manufacturing equipment, such as ramp times for valve actuation. The set of historical metrology data 264-1 may include one or more measurements of interest of properties of substrates. The set of historical metrology data 264-1 may include virtual metrology data, e.g., generated based on data obtained during or between process operations of a substrate. The model may be configured to accept indications of manufacturing parameters and metrology data (e.g., current manufacturing parameters and current metrology data) as input and generate mappings between process inputs and substrate performance as output. In some embodiments, data set generator 272 may train a model using historical manufacturing parameters as training input and corresponding historical metrology data as target output, and capture the mappings implicitly in the resulting parameters of the model.

Data set generator 272 may be used to generate data sets for any type of model used in association with enhanced process control. Data set generator 272 may be used to generate data for any type of machine learning model that takes as input historical manufacturing parameter data and/or historical metrology data. Data set generator 272 may be used to generate data for a machine learning model that generates input/output mappings (e.g., process knob/substrate property mappings, potentially multi-dimensional and non-linear mappings included). Data set generator 272 may be used to generate data for a model that performs virtual metrology operations (e.g., data input 210 may include spectral measurements or other accessible measurements, and target output 220 may include measured metrology). Data set generator 272 may be used to generate data for a process disturbance model (e.g., a model that updates operations of a run-to-run controller of an enhanced process control platform based on differences in incoming substrates, upstream processing, etc.). Data set generator 272 may be used to generate data for a model that performs process control, e.g., a digital twin process control model.

In some embodiments, data set generator 272 generates a data set (e.g., training set, validating set, testing set) that includes one or more data inputs 210 (e.g., training input, validating input, testing input). Data inputs 210 may be provided to training engine 182, validating engine 184, or testing engine 186. The data set may be used to train, validate, or test the model (e.g., model 190 of FIG. 1).

In some embodiments, data input 210 may include one or more sets of data. As an example, system 200 may produce sets of manufacturing parameter data that may include one or more of parameter data from one or more types of components, combinations of parameter data from one or more types of components, patterns from parameter data from one or more types of components, or the like. In some embodiments, target output 220 may include sets of output related to the various sets of data input 210.

In some embodiments, data set generator 272 may generate a first data input corresponding to a first set of manufacturing parameters 252-1 and a first set of historical metrology data 264-1 to train, validate, or test a first machine learning model. Data set generator 272 may generate a second data input corresponding to a second set of historical manufacturing parameter data and historical metrology data (e.g., a set of historical metrology data 252-2 and historical metrology data 264-2, not shown) to train, validate, or test a second machine learning model. Further sets of historical data may further be utilized in generating further machine learning models. Any number of sets of historical data may be utilized in generating any number of machine learning models, up to a final set, set of historical manufacturing parameters 252-N and set of historical metrology data 264-N (N representing any target quantity of data sets, models, etc.).

In some embodiments, data set generator 272 may generate a first data input corresponding to a first set of historical manufacturing parameters 252-1 and/or first set of historical metrology data 264-1 to train, validate, or test a first machine learning model. Data set generator 272 may generate a second data input corresponding to a second set of historical manufacturing parameters 252-2 and/or a second set of metrology data 264-2 (not shown) to train, validate, or test a second machine learning model.

In some embodiments, data set generator 272 generates a data set (e.g., training set, validating set, testing set) that includes one or more data inputs 210 (e.g., training input, validating input, testing input) and may include one or more target outputs 220 that correspond to the data inputs 210. The data set may also include mapping data that maps the data inputs 210 to the target outputs 220. In some embodiments, data set generator 272 may generate data for training a model configured to output relevant to preventing particle defect formation, by generating data sets including output predictive defect data 268. Data inputs 210 may also be referred to as “features,” “attributes,” or “information.” In some embodiments, data set generator 272 may provide the data set to training engine 182, validating engine 184, or testing engine 186, where the data set is used to train, validate, or test the model (e.g., one of the machine learning models that are included in model 190, ensemble model 190, etc.).

In some embodiments, subsequent to generating a data set and training, validating, or testing a machine learning model using the data set, the model may be further trained, validated, or tested, or adjusted (e.g., adjusting weights or parameters associated with input data of the model, such as connection weights in a neural network).

FIG. 3 is a block diagram illustrating system 300 for generating output data (e.g., predictive data 168 of FIG. 1), according to some embodiments. In some embodiments, system 300 may be used in conjunction with a model (e.g., physics-based, reduced order, data-based, machine learning, or the like) configured to generate predictive data related to an enhanced process control platform. In some embodiments, system 300 is utilized for generating output data by a model such as model 190 of FIG. 1. In some embodiments, system 300 may be used in conjunction with a model to determine a corrective action associated with manufacturing equipment. In some embodiments, system 300 may be used in conjunction with a machine learning model to cluster or classify substrates or substrate defects. System 300 may be used in conjunction with a machine learning model with a different function than those listed, associated with a manufacturing system.

At block 310, system 300 (e.g., components of predictive system 110 of FIG. 1) performs data partitioning (e.g., via data set generator 172 of server machine 170 of FIG. 1) of data to be used in training, validating, and/or testing a model, such as a machine learning model. In some embodiments, substrate processing data 364 includes historical data, such as historical metrology data (e.g., measured substrate properties and/or virtual metrology), historical manufacturing parameter data, historical classification data (e.g., classification of whether substrates meet target threshold quality standards), measured chamber condition data (e.g., indicative of processing conditions), etc. In some embodiments, e.g., when utilizing physics-based model data to train a machine learning model, substrate processing data 364 may include data output by a physics-based model (e.g., a computationally expensive physical model). Substrate processing data 364 may undergo data partitioning at block 310 to generate training set 302, validation set 304, and testing set 306. For example, the training set may be 60% of the training data, the validation set may be 20% of the training data, and the testing set may be 20% of the training data.

The generation of training set 302, validation set 304, and testing set 306 may be tailored for a particular application. For example, the training set may be 60% of the training data, the validation set may be 20% of the training data, and the testing set may be 20% of the training data. System 300 may generate a plurality of sets of features for each of the training set, the validation set, and the testing set. For example, if substrate processing data 364 includes manufacturing parameters, including features derived from 20 recipe parameters and 10 hardware parameters, the data may be divided into a first set of features including recipe parameters 1-10 and a second set of features including recipe parameters 11-20. The hardware parameters may also be divided into sets, for instance a first set of hardware parameters including parameters 1-5, and a second set of hardware parameters including parameters 6-10. Either target input, target output, both, or neither may be divided into sets. Multiple models may be trained on different sets of data.

At block 312, system 300 performs model training (e.g., via training engine 182 of FIG. 1) using training set 302. Training of a machine learning model and/or of a physics-based model (e.g., a digital twin) may be achieved in a supervised learning manner, which involves providing a training dataset including labeled inputs through the model, observing its outputs, defining an error (by measuring the difference between the outputs and the label values), and using techniques such as deep gradient descent and backpropagation to tune the weights of the model such that the error is minimized. In many applications, repeating this process across the many labeled inputs in the training dataset yields a model that can produce correct output when presented with inputs that are different than the ones present in the training dataset. In some embodiments, training of a machine learning model may be achieved in an unsupervised manner, e.g., labels or classifications may not be supplied during training. An unsupervised model may be configured to perform anomaly detection, result clustering, etc.

For each training data item in the training dataset, the training data item may be input into the model (e.g., into the machine learning model). The model may then process the input training data item (e.g., one or more manufacturing parameter values, etc.) to generate an output. The output may include, for example, a mapping between a set of process inputs and a set of process outputs. The output may be compared to a label of the training data item (e.g., a previously determined mapping). In some embodiments, mappings between process inputs and metrology or substrate performance data may be performed in an unsupervised manner, e.g., mappings may be determined without providing target output data.

In the case of supervised learning (e.g., virtual metrology), processing logic may then compare the generated output (e.g., predicted metrology) to the label (e.g., measured metrology) that was included in the training data item. Processing logic determines an error (i.e., a classification error) based on the differences between the output and the label(s). Processing logic adjusts one or more weights and/or values of the model based on the error.

In the case of training a neural network, an error term or delta may be determined for each node in the artificial neural network. Based on this error, the artificial neural network adjusts one or more of its parameters for one or more of its nodes (the weights for one or more inputs of a node). Parameters may be updated in a back propagation manner, such that nodes at a highest layer are updated first, followed by nodes at a next layer, and so on. An artificial neural network contains multiple layers of “neurons”, where each layer receives as input values from neurons at a previous layer. The parameters for each neuron include weights associated with the values that are received from each of the neurons at a previous layer. Accordingly, adjusting the parameters may include adjusting the weights assigned to each of the inputs for one or more neurons at one or more layers in the artificial neural network.

System 300 may train multiple models using multiple sets of features of the training set 302 (e.g., a first set of features of the training set 302, a second set of features of the training set 302, etc.). For example, system 300 may train a model to generate a first trained model using the first set of features in the training set (e.g., manufacturing parameter data from components 1-10, condition predictions 1-10, etc.) and to generate a second trained model using the second set of features in the training set (e.g., manufacturing parameter data from components 11-20, modeling process chamber conditions 11-20, etc.). In some embodiments, the first trained model and the second trained model may be combined to generate a third trained model (e.g., which may be a better predictor than the first or the second trained model on its own). In some embodiments, sets of features used in comparing models may overlap (e.g., first set of features being parameters 1-15 and second set of features being parameters 5-20). In some embodiments, hundreds of models may be generated including models with various permutations of features and combinations of models.

At block 314, system 300 performs model validation (e.g., via validation engine 184 of FIG. 1) using the validation set 304. The system 300 may validate each of the trained models using a corresponding set of features of the validation set 304. For example, system 300 may validate the first trained model using the first set of features in the validation set (e.g., parameters 1-10 or conditions 1-10) and the second trained model using the second set of features in the validation set (e.g., parameters 11-20 or conditions 11-20). In some embodiments, system 300 may validate hundreds of models (e.g., models with various permutations of features, combinations of models, etc.) generated at block 312. At block 314, system 300 may determine an accuracy of each of the one or more trained models (e.g., via model validation) and may determine whether one or more of the trained models has an accuracy that meets a threshold accuracy. Responsive to determining that none of the trained models has an accuracy that meets a threshold accuracy, flow returns to block 312 where the system 300 performs model training using different sets of features of the training set. Responsive to determining that one or more of the trained models has an accuracy that meets a threshold accuracy, flow continues to block 316. System 300 may discard the trained models that have an accuracy that is below the threshold accuracy (e.g., based on the validation set).

At block 316, system 300 performs model selection (e.g., via selection engine 185 of FIG. 1) to determine which of the one or more trained models that meet the threshold accuracy has the highest accuracy (e.g., the selected model 308, based on the validating of block 314). Responsive to determining that two or more of the trained models that meet the threshold accuracy have the same accuracy, flow may return to block 312 where the system 300 performs model training using further refined training sets corresponding to further refined sets of features for determining a trained model that has the highest accuracy.

At block 318, system 300 performs model testing (e.g., via testing engine 186 of FIG. 1) using testing set 306 to test selected model 308. System 300 may test, using the first set of features in the testing set (e.g., parameters 1-10), the first trained model to determine the first trained model meets a threshold accuracy. Determining whether the first trained model meets a threshold accuracy may be based on the first set of features of testing set 306. Responsive to accuracy of the selected model 308 not meeting the threshold accuracy, flow continues to block 312 where system 300 performs model training (e.g., retraining) using different training sets corresponding to different sets of features. Accuracy of selected model 308 may not meet threshold accuracy if selected model 308 is overly fit to the training set 302 and/or validation set 304. Accuracy of selected model 308 may not meet threshold accuracy if selected model 308 is not applicable to other data sets, including testing set 306. Training using different features may include training using data from different sensors, different manufacturing parameters, etc. Responsive to determining that selected model 308 has an accuracy that meets a threshold accuracy based on testing set 306, flow continues to block 320. In at least block 312, the model may learn patterns in the training data to make predictions. In block 318, the system 300 may apply the model on the remaining data (e.g., testing set 306) to test the predictions.

At block 320, system 300 uses the trained model (e.g., selected model 308) to receive current data 322 and determines (e.g., extracts), from the output of the trained model, output mapping data 324. Current data 322 may be manufacturing parameters related to a process, operation, or action of interest. Current data 322 may be manufacturing parameters related to a process under development, redevelopment, investigation, etc. Current data 322 may include virtual or measured metrology data in association with substrate processing data. A corrective action associated with the manufacturing equipment 124 of FIG. 1 may be performed in view of output mapping data 324. In some embodiments, current data 322 may correspond to the same types of features in the historical data used to train the machine learning model. In some embodiments, current data 322 corresponds to a subset of the types of features in historical data that are used to train selected model 308. For example, a machine learning model may be trained using a number of manufacturing parameters, and configured to generate output based on a subset of the manufacturing parameters.

In some embodiments, the performance of a machine learning model trained, validated, and tested by system 300 may deteriorate. For example, a manufacturing system associated with the trained machine learning model may undergo a gradual change or a sudden change. A change in the manufacturing system may result in decreased performance of the trained machine learning model. A new model may be generated to replace the machine learning model with decreased performance. The new model may be generated by altering the old model by retraining, by generating a new model, etc.

Generation of a new model may include providing additional training data 346. Generation of a new model may further include providing current data 322, e.g., data that has been used by the model to make predictions. In some embodiments, current data 322 when provided for generation of a new model may be labeled with an indication of an accuracy of predictions generated by the model based on current data 322. Additional training data 346 may be provided to model training 312 for generation of one or more new machine learning models, updating, retraining, and/or refining of selected model 308, etc.

In some embodiments, one or more of the acts 310-320 may occur in various orders and/or with other acts not presented and described herein. In some embodiments, one or more of acts 310-320 may not be performed. For example, in some embodiments, one or more of data partitioning of block 310, model validation of block 314, model selection of block 316, or model testing of block 318 may not be performed.

FIGS. 4A-C are flow diagrams of methods 400A-C associated with utilizing models to predict and/or correct substrate particle defect root causes, according to certain embodiments. Methods 400A-C may be performed by processing logic that may include hardware (e.g., circuitry, dedicated logic, programmable logic, microcode, processing device, etc.), software (such as instructions run on a processing device, a general purpose computer system, or a dedicated machine), firmware, microcode, or a combination thereof. In some embodiment, methods 400A-C may be performed, in part, by predictive system 110. Method 400A may be performed, in part, by predictive system 110 (e.g., server machine 170 and data set generator 172 of FIG. 1, data set generator 272 of FIG. 2). Predictive system 110 may use method 400A to generate a data set to at least one of train, validate, or test a model (e.g., a physics-based model, a reduced order model, a machine learning model), in accordance with embodiments of the disclosure. Methods 400B-C may be performed by predictive server 112 (e.g., predictive component 114), control module 115, and/or server machine 180 (e.g., training, validating, and testing operations may be performed by server machine 180). In some embodiments, a non-transitory machine-readable storage medium stores instructions that when executed by a processing device (e.g., of predictive system 110, of server machine 180, of predictive server 112, etc.) cause the processing device to perform one or more of methods 400A-C.

For simplicity of explanation, methods 400A-C are depicted and described as a series of operations. However, operations in accordance with this disclosure can occur in various orders and/or concurrently and with other operations not presented and described herein. Furthermore, not all illustrated operations may be performed to implement methods 400A-C in accordance with the disclosed subject matter. In addition, those skilled in the art will understand and appreciate that methods 400A-C could alternatively be represented as a series of interrelated states via a state diagram or events.

FIG. 4A is a flow diagram of a method 400A for generating a data set for a model, according to some embodiments. Referring to FIG. 4A, in some embodiments, at block 401 the processing logic implementing method 400A initializes a training set T to an empty set.

At block 402, processing logic generates first data input (e.g., first training input, first validating input) that may include one or more of manufacturing parameters, metrology data, process chamber condition data, etc. In some embodiments, the first data input may include a first set of features for types of data and a second data input may include a second set of features for types of data (e.g., as described with respect to FIG. 3). Input data may include historical data and/or data output by a model (e.g., a physics-based model output used for training a machine learning model).

In some embodiments, at block 403, processing logic optionally generates a first target output for one or more of the data inputs (e.g., first data input). In some embodiments, the input includes one or more measured properties for generating virtual metrology and the target output includes measured metrology. In some embodiments, the input includes an indication of an upstream disturbance and output includes an adjustment to operations of a process control module (e.g., based on subject matter expertise, based on data mining of historical disturbances, etc.). In some embodiments, the target output is a recommended corrective action, such as an update to one or more recipe set points or other process recipe parameters. In some embodiments, the first target output is predictive data.

At block 404, processing logic optionally generates mapping data that is indicative of an input/output mapping. The input/output mapping (or mapping data) may refer to the data input (e.g., one or more of the data inputs described herein), the target output for the data input, and an association between the data input(s) and the target output. In some embodiments, such as in association with machine learning models where no target output is provided, block 404 may not be executed.

At block 405, processing logic adds the mapping data generated at block 404 to data set T, in some embodiments.

At block 406, processing logic branches based on whether data set Tis sufficient for at least one of training, validating, and/or testing a machine learning model, such as synthetic data generator 174 or model 190 of FIG. 1. If so, execution proceeds to block 407, otherwise, execution continues back at block 402. It should be noted that in some embodiments, the sufficiency of data set T may be determined based simply on the number of inputs, mapped in some embodiments to outputs, in the data set, while in some other embodiments, the sufficiency of data set T may be determined based on one or more other criteria (e.g., a measure of diversity of the data examples, accuracy, etc.) in addition to, or instead of, the number of inputs.

At block 407, processing logic provides data set T (e.g., to server machine 180) to train, validate, and/or test machine learning model 190. In some embodiments, data set T is a training set and is provided to training engine 182 of server machine 180 to perform the training. In some embodiments, data set T is a validation set and is provided to validation engine 184 of server machine 180 to perform the validating. In some embodiments, data set T is a testing set and is provided to testing engine 186 of server machine 180 to perform the testing. In the case of a neural network, for example, input values of a given input/output mapping (e.g., numerical values associated with data inputs 210) are input to the neural network, and output values (e.g., numerical values associated with target outputs 220) of the input/output mapping are stored in the output nodes of the neural network. The connection weights in the neural network are then adjusted in accordance with a learning algorithm (e.g., back propagation, etc.), and the procedure is repeated for the other input/output mappings in data set T. After block 407, a model (e.g., model 190) can be at least one of trained using training engine 182 of server machine 180, validated using validating engine 184 of server machine 180, or tested using testing engine 186 of server machine 180. The trained model may be implemented by predictive component 114 (of predictive server 112) to generate predictive data 168 for performing signal processing, or for performing a corrective action associated with manufacturing equipment 124.

FIG. 4B is a flow diagram of a method 400 for utilizing enhanced process control operations for improving process operations, according to some embodiments. At block 410, a run-to-run controller (e.g., process logic executing operations of a run-to-run controller for enhanced process control) obtains first metrology data of a first substrate. The first metrology data may include measured metrology data. Measured metrology data may be or include data measured by standalone metrology equipment, in-line metrology equipment, integrated metrology equipment, or any other type of metrology equipment. The first metrology data may be or include virtual metrology data. Virtual metrology may include metrology data generated by a model based on measured data that can be correlated with properties of interest of the substrate. For example, spectral reflection data may be used to calculate a film thickness of a substrate. Such data may be collected during or between process operations, in some systems, such as systems including on-board sensing for virtual metrology.

In some embodiments, the substrate may be a substrate that was recently processed by the process chamber associated with the run-to-run controller. The substrate may have been proceeded in accordance with the first processing operation (e.g., may have been processed by the process chamber executing a process recipe configured to perform the first processing operation). In some embodiments, the substrate may be a substrate that is to be processed by the process chamber. For example, control of the process chamber may be linked to performance of substrates incoming from a previous processing operation.

The run-to-run controller may include a number of models configured to enact enhanced process control. The enhanced process control may be performed using one or more machine learning models, optimized modeling, or the like. The run-to-run controller may include a first model that is configured to determine a relationship between substrate metrology and one or more process knobs. The first model may be or include a machine learning or artificial intelligence model. The first model may be trained to determine differences between a standard or expected set of input/output mappings, and observed input/output mappings. The first model may be configured to generate input/output mappings (e.g., relationships between any number of process inputs and any number of substrate properties of interest). The first model may be configured to estimate relationships between process knobs and substrate properties in a limited range of all possible process conditions. The first model may be configured to estimate relationships in a restricted portion of process condition space, for example in the vicinity of process condition space near process conditions associated with the process recipe of interest.

In some embodiments, the run-to-run controller may include a second model. The second model may be or include a constrained optimizer, such as a multiple input/multiple output optimizer model. In some embodiments, the first model may output a set of relationships, and the second model may be used to leverage the set of relationships to produce optimized process parameters, subject to target constraints. The second model may be configured to recommend one or more corrective actions (e.g., process recipe updates) based on the relationships between process knob inputs and substrate property outputs developed by the first model.

In some embodiments, updating the process recipe may include adjusting parameters for subsequent substrates based on data collected from the first substrate. For example, between processing of two substrates updates to the process recipe may be enacted, or during processing of a third substrate processed between a first and second substrate, data from the first substrate may be used to update processing conditions for the second substrate.

At block 412, process logic of the run-to-run controller processes the first metrology data by providing the first metrology data as input to the first model. The first model determines one or more relationships between process inputs (e.g., measured conditions, manufacturing parameters, recipe setpoints, etc.) and process outputs (e.g., substrate properties, virtual metrology, etc.). The first model may generate input/output mappings for use by the second model.

At block 413, process logic optionally obtains second metrology data of a second substrate. The process logic may process the second metrology data by the first model. Output from the first model based on the second substrate may be provided to the second model for optimization operations. Updates to future processing operations may be based on the first substrate and the second substrate. Determinations to make one or more changes to process conditions, recipes, or the like, may be based on measured data of multiple substrates in embodiments. In some embodiments, a threshold number of substrates may be used to determine whether to enact one or more changes to the processing system. In some embodiments, a threshold confidence level may be used, or a combination of factors may be used, in determining when to enact changes, which recommended changes to enact, etc.

At block 414, process logic determines, using the second model, a recommended one or more process recipe updates. The process recipe updates may be generated based on the input/output mappings, based on the relationships between first metrology data and the one or more process knobs, etc. Recommended updates may be based on data from multiple substrates, including the second substrate and/or further substrates.

At block 416, process logic optionally obtains data indicative of disturbances present in processing operations of substrates incoming to the processing operation. For example, the first substrate may be processed, measured, etc. Additional data related to a difference between the first substrate and one or more subsequent substrates arriving from upstream processing may also be consumed to generate recommended updates. For example, upstream disturbances may be accounted for by the first model or the second model (e.g., these models may additionally be configured or trained based on historical disturbance data to account for these disturbances in making accurate predictions).

The disturbances present in incoming substrate processing may include differences in substrate properties caused by upstream processing (e.g., based on on-board or virtual metrology). The disturbances may include indications of changing parameters of upstream equipment, such as changes to process inputs provided to previous processing operations of the incoming substrates. The disturbance data may include indications of drift, aging, and/or changes in hardware or components of equipment used to process incoming substrates upstream in a processing procedure.

At block 417, the disturbance data is provided to a trained machine learning disturbance model. The model may be configured to obtain disturbance data, and output one or more adjustments for further data analysis or manipulation. For example, the disturbance model may be configured to output changes to be made to data provided as input to another model (e.g., the first model) that will account for the upstream disturbances. The disturbance model may be configured to adjust output of another model (e.g., the first model) to account for the disturbances. The disturbance model may be configured to adjust operations of another model (e.g., the first model) by providing changes to parameters of the model, providing additional input adjusting operation of the model, or the like. The disturbance model may be trained to perform any of these operations by providing appropriate disturbance data as training input and corresponding output data, of the type of interest, as target output. The disturbance model may provide output to the run-to-run controller to adjust operations of the run-to-run controller.

At block 420, process logic updates a recipe associated with the first processing operation based on the recommended one or more process recipe updates (e.g., output by the second model of the run-to-run controller). The process recipe updates may include adjusting recipe parameters for future substrates to be processed by the same processing operation and/or the same process chamber as the first substrate. In some embodiments, subsequent substrates are processed in accordance with the updated version of the processing operation.

In some embodiments, one or more adjustments to a process recipe may be further based on a level of certainty or confidence output by one or more models. For example, machine learning models may output a level of certainty that predictions made by the model are accurate. The level of certainty may be used to determine whether to enact any recommended changes. The level of certainty may be used to determine to what extent to enact the changes. For example, a low confidence metric may cause a change to be made, but a numerically smaller change to one or more parameters than would be enacted in connection with a high confidence metric. The level of certainty may be used to determine prediction horizons and/or control horizons. For example, a model recommending or enacting changes may process data associated with several substrates to determine recommended process adjustments. Substrates that are associated with higher certainty recommendations may be used in decision making for a longer period of time, may have weighting factors that cause their influence on decision making to decay more slowly, etc. Prediction horizons may include how far into the future predictions are made. Control horizons may include how far into the future control inputs are calculated. Control horizons and predictions horizons may be adjusted together or separately. In some embodiments, optimization weights may be adjusted based on certainty or confidence metrics. For example, an optimizer may include matrix optimization operations, such as optimizations based on R and Q matrices. Such optimizations may include parameters related to a level of emphasis the optimizer places on penalizing large control changes, and optimizing target variable values. In cases of lower certainty, for example, penalties for large changes may be increased compared to situations with model output of high certainty. In some embodiments, control response strength may be adjusted based on a level of certainty. For example, a control response may be dampened responsive to a low confidence level output by the model with respect to the recommended adjustment.

FIG. 4C is a flow diagram of a method 400C for utilizing a run-to-run controller to update a process operation control module, according to some embodiments. At block 420, process logic executing a run-to-run controller obtains first metrology data of a first substrate. The first substrate may have been recently processed by a process chamber in accordance with a first process operation (e.g., following an associated process recipe). The metrology data may be virtual metrology data based on on-board sensing data.

The run-to-run controller may include a first model and a second model, configured to determine relationships between process inputs and outputs (e.g., input/output mappings) and recommend adjustments to process conditions or recipes based on the relationships. Operations of the first and second model may be similar to the operations described with respect to block 410 of FIG. 4B. In some embodiments, the second model may be a constrained optimizer configured to recommend adjustments to another control module. For example, a digital twin control model (e.g., process chamber digital twin feedback model) may be updated based on output of the second model.

At block 421, output from the run-to-run controller is provided to the process chamber digital twin feedback model. The feedback model is configured to adjust operation of an associated process chamber (e.g., the process chamber responsible for processing the first substrate). In some embodiments, the feedback model adjusts processing of the process chamber based on sensor data of the chamber. For example, the feedback model may use sensor data to maintain process conditions within target thresholds. In some cases, the feedback model may make frequent adjustments (e.g., adjustments may be made during processing of a substrate, adjustments may be made between substrates within a lot or set of substrates, or the like). In some embodiments, the feedback model may be updated based on output from the run-to-run controller, and may perform differently based on the updates. In some embodiments, updates to the feedback model may be less frequent than actions enacted by the feedback model, e.g., updates to the feedback model may occur between substrates, after a few substrates, between lots or sets of substrates, or the like.

At block 422, process logic updates control parameters of the process chamber digital twin feedback model based on the output from the run-to-run controller. At block 423, process logic optionally provides a control signal to the process chamber based on the updated control parameters, e.g., output of the feedback model may be provided to adjust operations of the process chamber.

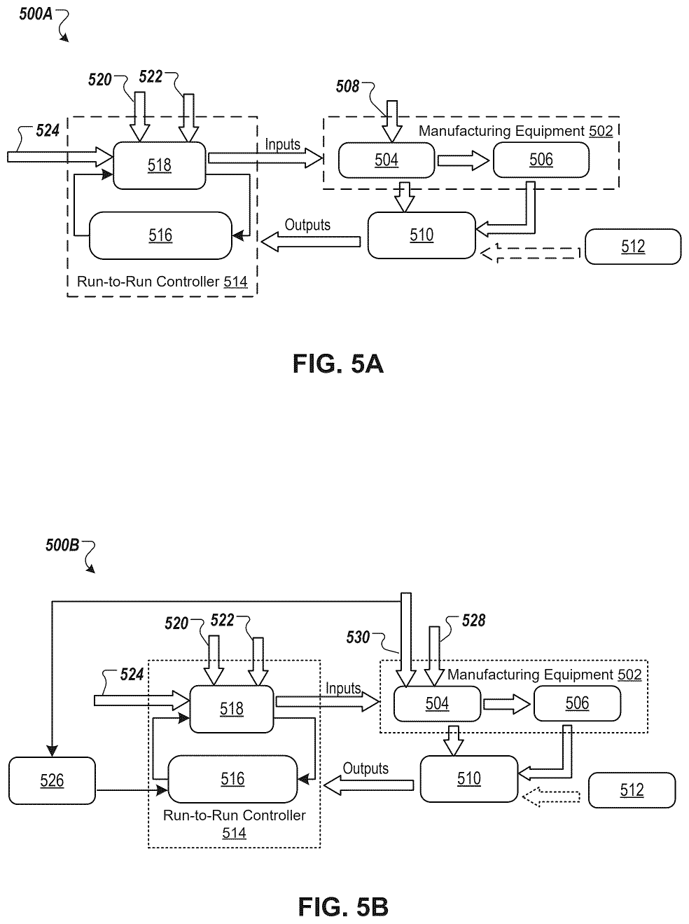

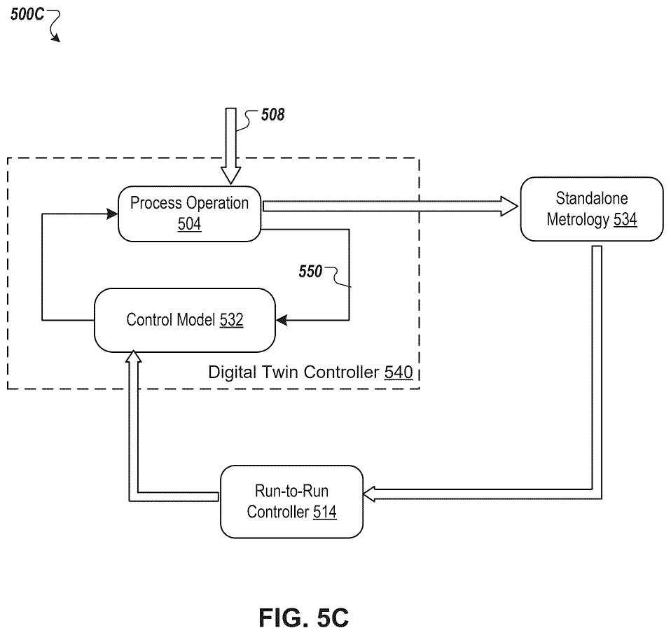

FIG. 5A depicts a block diagram of a work flow 500A for execution of an enhanced process control platform, according to some embodiments. Work flow 500A includes operations of manufacturing equipment 502, including process operation 504 and substrate sensing 506. Manufacturing equipment 502 may include components installed in, at, or in association with a process tool, process chamber, process facility, or the like. For example, manufacturing equipment 502 may include a process chamber and associated components (e.g., load lock, transfer chamber, gas supply system, exhaust system, etc.), as well as one or more computing devices that may execute control systems for the manufacturing equipment 502. Local computing devices of the manufacturing equipment 502 (e.g., edge computing devices) may execute one or more operations of the enhanced process control platform. In some embodiments, one or more computing devices included in manufacturing equipment 502 may be in constant, continual, periodic, scheduled, sporadic, or the like communication (e.g., via a network) with one or more external computing devices. For example, model training, model updating, model retraining, program updates, and the like may be enacted by a central server, which receives input from manufacturing equipment 502 (e.g., retraining may be based on indications of accuracy received from manufacturing equipment 502) and provides updates to manufacturing equipment 502.

Manufacturing equipment 502 may perform a process operation 504. Process operation 504 may be executed according to a process recipe, e.g., enacted by a computing device of manufacturing equipment 502. Process operation 504 may be affected by disturbances 508, e.g., differences in incoming materials from upstream processes, differences in manufacturing equipment compared to equipment upon which one or more models are based, and the like. Data may be generated by process operation 504. One or more substrates may be processed at process operation 504.

Substrates processed in accordance with process operation 504 may be provided to substrate sensing 506. Substrate sensing 506 may include one or more sensors installed in a process tool. An example of substrate sensing 506 is performed by optical sensors configured to measure optical reflectance of substrates being delivered to or recovered from a process chamber (e.g., a process chamber of manufacturing equipment 502). Substrate sensing 506 may include on-board sensing. Substrate sensing 506 may include in-line metrology, e.g., measurements performed at or near a process tool, but not integrated with the tool. Substrate sensing 506 may include measurements of a substrate output by process operation 504, from which properties of the substrate may be inferred, predicted, calculated, or the like.

Data from substrate process operation 504 and substrate sensing 506 may be provided to virtual metrology model 510. Virtual metrology model 510 may be a machine learning model. Virtual metrology model 510 may be a trained machine learning model. Virtual metrology model 510 may be a physics-based model or another type of model. Virtual metrology model 510 may generate predicted properties of the substrate based on the input data. Virtual metrology model 510 may further receive, as input, external reference metrology 512. External reference metrology 512 may include target properties of a substrate. External reference metrology 512 may include measured metrology of one or more substrates, e.g., measurements of substrates that satisfy one or more target conditions. External reference metrology 512 may improve predictive power of virtual metrology model 510, improve accuracy of virtual metrology model 510, improve confidence of virtual metrology model 510, or the like.

Output of virtual metrology model 510 may be provided to a run-to-run controller 514, which may include multiple components. Output of virtual metrology model 510 may be or include process outputs, e.g., indications of effects of process operation 504 on the substrate.

Virtual metrology data may be provided to input/output model 516. Input/output model 516 may be a trained machine learning model. Input/output model 516 may be a physics-based model. Input/output model 516 may be another type of model. Input/output model 516 may receive model input, and generate model output for use by run-to-run controller 514. Input/output model 516 may generate, based on virtual metrology, process operations, process recipes, etc., indications of relationships between process input variables (e.g., process knobs, process conditions, etc.) and process output variables (e.g., substrate properties, substrate performance, substrate metrology, etc.). Input/output model 516 may generate indications of various effects that adjustments to process inputs may have on process outputs, e.g., how processing conditions may adjust metrology in the vicinity (in process space) of substrate process operation 504. The input/output model 516 may generate predictions of how a single input affects a single output. Input/output model 516 may generate predictions of how a single input affects multiple outputs. Input/output model 516 may generate predictions of multiple process inputs influencing a single process output. Input/output model 516 may generate predictions of multiple process inputs influencing multiple process outputs. Predictions of input/output model 516 may be inter-dependent, e.g., values of one or more relationship parameters may depend on values of other relationship parameters.

Input/output model 516 may provide model output indicative of process input/process output relationships to optimizer model 518. Optimizer model 518 may be a constrained optimizer, and may work within constraints (e.g., boundary conditions) provided as constraints 520. Optimizer model 518 may work to minimize a cost function 522 within the bounds provided by constraints 520. Cost function 522 may include one or more parameters for generating output of optimizer model 518 predicted to generate a substrate having one or more target properties, e.g., in accordance with target 524. Optimizer model 518 may include functions to take into account further design goals, e.g., by providing a numerical penalty as a distance from the design goals is increased. For example, optimizer model 518 may include parameters to maintain substrate properties close to target 524, and additional parameters related to other goals, potentially including increasing process throughput, increasing process reliability, decreasing defects, decreasing energy or material consumption, decreasing environmental impact, or the like. These predictions or instructions may be provided as inputs (e.g., process inputs) to update future operations of manufacturing equipment 502.

In some embodiments, input/output model 516 may further provide confidence data (e.g., a confidence that input/output model 516 has generated accurate predictions) to optimizer model 518. Optimizer model 518 may adjust operations based on the confidence data. In some embodiments, a less drastic action may be taken based on low-confidence predictions. Predictions performed by optimizer model 518 may be adjusted by confidence data. A duration of predictions generated by optimizer model 518 may be reduced in response to low-confidence data. For example, prediction horizons and control horizons may be based on confidence data. Various parameters of the optimizer (e.g., Q and R matrix parameters of a decomposition of cost function 522) may be adjusted based on confidence data. Control response may be adjusted based on confidence data. For example, a dampened response may be utilized based on low confidence data.

In some embodiments, output of a single process (e.g., a single substrate, a single semiconductor wafer) may be utilized to adjust operation of a single future process (e.g., a single future substrate for processing). In some embodiments, output of a single process may be utilized to adjust operations of multiple future processes. In some embodiments, data associated with multiple substrates may be utilized to update processing of further multiple substrates, e.g., in a boxcar fashion, a progressive window fashion, or the like. A “run,” for purposes of describing the operations of the run-to-run controller 514, may include any target number of substrates, a variable number of substrates, a customizable number of substrates, or the like.

In some embodiments, run time operations for the run-to-run controller 514 may occur between subsequent process operations (e.g., between performing the process operation in question on a first substrate, data may be generated and utilized for updating process conditions for a second substrate). In some embodiments, a delay of one or more substrates may be introduced, e.g., when transitioning between process operations is performed more quickly than data generation and calculations in association with chamber updates. For example, data may be generated before (e.g., on-board sensing, disturbance data), during (e.g., tool sensor data), and/or after (e.g., further on-board sensing) processing of a first substrate. Calculations related to updating process conditions may be performed by the run-to-run controller during processing of a second substrate. Updates to process operations may be enacted for processing of a third substrate. Any number of substrates may be used as input data, any number of substrates or operations in progress may be processed during calculations, and any number of subsequent substrate operations may benefit from updates from the run-to-run controller. In some embodiments, data received in connection with one process chamber, set of manufacturing equipment, process tool, or the like may be utilized (e.g., either for run-to-run control or for model training purposes) in improving processing operations for another chamber, set of manufacturing equipment, tool, facility, or the like.

In some embodiments, constraints 520 provided may include update timing constraints. For example, a first process variable may be able to be adjusted frequently, while a second process variable may be constrained to less frequent adjustment (e.g., may only be adjusted between blocks of a target number of substrates processed). Timing update constraints may be utilized in the case of a constrained multiple input/multiple output optimizer. As an example, virtual metrology may include a critical dimension measurement at locations across a substrate, and a critical dimension tilt angle measurement at locations across the substrate. One or more of these substrate properties may be affected by multiple process operation inputs, such as temperature distribution across the substrate during processing (e.g., as controlled by power provided to various heaters of the manufacturing equipment 502) and/or a ring height of an edge ring. In some embodiments, an edge ring height may more effectively counteract slow drifts in the manufacturing system, while temperature updates may be used to correct more agile changes in processing (e.g., including disturbances of incoming substrates). The run-to-run controller may be constrained to adjust a ring height infrequently (e.g., a maximum of once per lot of substrate manufacturing, or any other target update frequency), while being free to adjust the temperature profile for substrate processing more frequently (e.g., for a smaller number of substrates as data input, a smaller number of substrates as control output, individualized based on disturbance data, or the like). Any process variables may be constrained to be adjusted at a maximum frequency to reduce likelihood of errors, to reduce outlier effects, to reduce inefficiencies accumulated by frequent adjustment, or the like.

FIG. 5B is a block diagram of a work flow 500B for operation of an enhanced process control platform, including a disturbance model 526, according to some embodiments. Work flow 500B includes operations of manufacturing equipment 502. Manufacturing equipment 502 includes process operation 504 and substrate sensing 506.

Disturbances provided to process operation 504 include measured disturbances 530 and unmeasured disturbances 528. In additional to affecting substrate processing by providing different input conditions (e.g., differences in underlying substrate structure due to differences in upstream processing operations), measured disturbances also may provide data for use by the enhanced process control platform. In some embodiments, both measured disturbances 530 and unmeasured disturbances 528 may act as input to process operation 504 (e.g., including physical disturbances of the substrate), with measured disturbances 530 providing data which may be used for one or both of updates to the process operation 504 (e.g., immediate updates) and for use by disturbance model 526 (e.g., for improving operations of run-to-run controller 514).

Measured disturbances 530 may include feedforward metrology from upstream processes. Measured disturbances 530 may include chamber drift data. Measured disturbances 530 may include chamber condition data. Measured disturbances 530 may include equipment parameters of upstream equipment. Manufacturing equipment related to disturbance data may include the same process chamber associated with process operation 504 of a different process chamber. Disturbance data may be related to the same or different manufacturing tool, facility, chamber type, process type, or the like. Disturbance data may be related to raw materials, e.g., properties of a bare substrate before any processing is performed. Disturbance model 526 may be trained on a history of measured differences upstream performance. Disturbance model 526 may be trained on data indicative of how incoming disturbances manifest in process outcomes, substrate properties, substrate performance, etc. In some embodiments, disturbance model 526 may be a trained machine learning model. In some embodiments, data (e.g., disturbance data) may accompany a substrate virtually as it is provided to a set of processing operations, to advance processing toward a final product.

FIG. 5C is a block diagram of a work flow 500C for operation of a run-to-run controller interacting with another control loop for control of manufacturing equipment, according to some embodiments. Work flow 500C includes process control loop 550, for adjusting operation of a process chamber, process tool, manufacturing equipment, process operation 504, or the like. During processing of a substrate, process operation 504 may generate data (e.g., sensor data, trace data, tool sensor data, etc.) that may be utilized in control of the process operation 504. Enacting control of the process operation may be performed using a control model 532.

Control model 532 may be configured to perform updates based on incoming data from process operation 504. Control model 532 may be digital twin of the process chamber associated with process operation 504. Control model 532 may be a physics-based digital twin model. Control model 532 may be a trained machine learning model. Control model 532 may be another type of model, e.g., statistical, rule-based, or the like. Control model 532 may be configured to provide model output that corresponds to updates to process operation inputs, which are used to adjust subsequent process operations.

Substrate measurements may be performed based on substrate processed by process operation 504. Measurements may include virtual metrology, integrated metrology, in-line metrology, or on-board sensing as previously discussed. Further, external or standalone metrology 534 may be performed to determine properties of substrates output by process operation 504. In the case of standalone or external metrology, such measurements may be delayed and/or infrequent compared to on-board sensing, e.g., due to time, cost, location, etc., of external measurement methods and equipment.

Run-to-run controller 514 may obtain as input metrology data (e.g., from standalone metrology 534, on-board sensing, virtual metrology, etc.) and use the metrology data to recommend updates to operations of the process control loop 550. In some embodiments, output of the run-to-run controller 514 may be used to adjust parameters of the control model 532, e.g., to adjust weights and/or biases of a trained machine learning model, to adjust coefficients or other parameters of a physics-based digital twin model, to adjust control thresholds, or the like. In some embodiments, output of the control model 532 may be frequent (e.g., control updates may be made to every substrate, a set of substrates, windows including a number of substrate, etc.), while updates to control model 532 based on model output of run-to-run controller 514 may be less frequent (e.g., at a frequency based on frequency of obtaining data from standalone metrology 534).

Run-to-run controller 514 may interact with the second control loop (process control loop 550) to improve operations of the second control loop, to provide robustness to the second control loop in light of adjustments to chamber operations that occur over different time scales, etc., while still maintaining the communication of the process operation 504 with control model 532, e.g., without providing multiple potentially conflicting control inputs to process operation 504. Operations of run-to-run controller 514 may be or include aspects discussed in connection with work flows 500A-B.

In some embodiments, run-to-run controller 514 may be configured to adjust a first set of process knobs of process operation 504, and control model 532 (e.g., a digital twin control model) may be configured to adjust a second set of process knobs of process operation 504. The process knobs associated with run-to-run controller may be different than those associated with control model 532, may overlap with those associated with control model 532, may be the same process knobs as those associated with control model 532, etc. Run-to-run controller 514 may provide instructions for process knob adjustments to digital twin controller 540, control model 532, and/or processing equipment to directly adjust process operation 504. Any combination of these instructions may be provided, e.g., run-to-run controller 514 may provide constraints for one or more process knobs to control model 532, and provide instructions to adjust one or more process knobs to process operation 504.

In some embodiments, there may be discrepancies between inputs recommended for a particular process knob between run-to-run controller 514 and control model 532. For example, process knobs directed by the run-to-run controller 514 and control model 532 may overlap. There are various schemes that may be applied for control of a system that includes directions from run-to-run controller 514 and control model 532. The two control systems may rely on each other, may learn from each other, may update each other, etc. In some embodiments, baselines of one or more of the systems may be reset, e.g., based on newly available information.

In some embodiments, both a digital twin controller and a run-to-run controller may tune common tuning knobs. In some cases, the control scheme may ensure that the latest value (e.g., latest confirmed value that produces satisfactory results) may be utilized. In some embodiments, a digital twin will compare current recommendations of shared tuning knobs with last known acceptably performing values of the run-to-run controller, and re-baseline or reset values of the digital twin controller based on the run-to-run controller recommendation. The digital twin controller may run at a higher frequency, e.g., based on the updates from the run-to-run controller which are associated with infrequent metrology measurements, and the digital twin controller may add additional adjustment on top of the baseline set by the run-to-run controller.

In some embodiments, the digital twin controller may make updates to tune the common tuning knobs. For example, the optimization procedure performed by the run-to-run controller may fix (e.g., separately for each iteration, wafer, set of wafers, control cycle, or the like) the values of the common tuning knobs accessible or usable by both the digital twin controller and the run-to-run controller, to a value selected by the digital twin controller. Every adjustment by the digital twin controller may reset the run-to-run controller. The run-to-run controller on any subsequent operations may use the updated values of the shared process knobs as constrained values, e.g., provided as constrained values to the optimizer model. If there are not updates from the digital twin model, the run-to-run controller may use the most recent updated values for any shared or common process knobs.

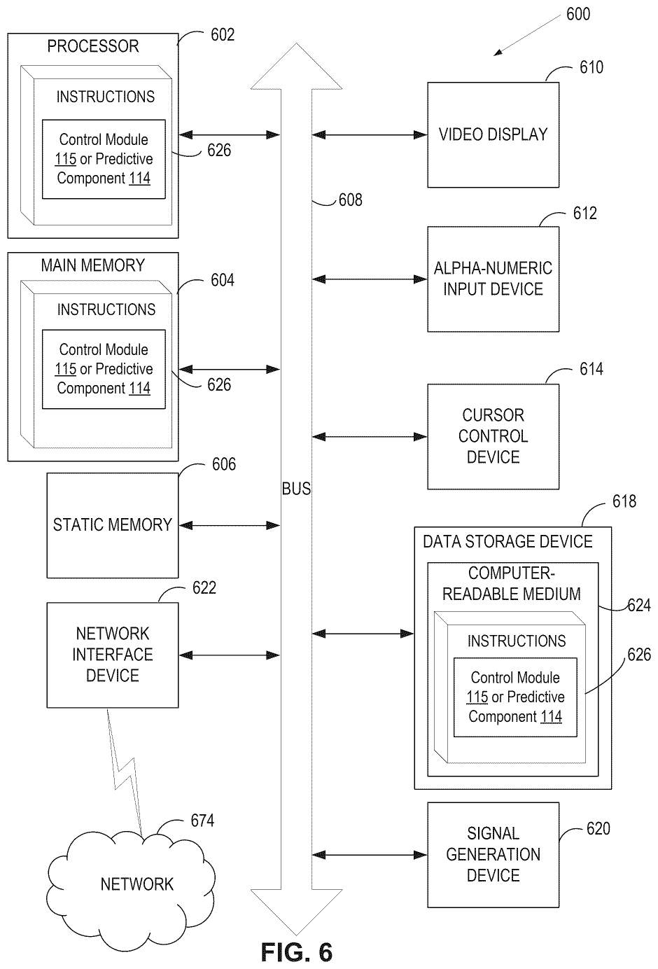

FIG. 6 is a block diagram illustrating a computer system 600, according to some embodiments. In some embodiments, computer system 600 may be connected (e.g., via a network, such as a Local Area Network (LAN), an intranet, an extranet, or the Internet) to other computer systems. Computer system 600 may operate in the capacity of a server or a client computer in a client-server environment, or as a peer computer in a peer-to-peer or distributed network environment. Computer system 600 may be provided by a personal computer (PC), a tablet PC, a Set-Top Box (STB), a Personal Digital Assistant (PDA), a cellular telephone, a web appliance, a server, a network router, switch or bridge, or any device capable of executing a set of instructions (sequential or otherwise) that specify actions to be taken by that device. Further, the term “computer” shall include any collection of computers that individually or jointly execute a set (or multiple sets) of instructions to perform any one or more of the methods described herein.

In a further aspect, the computer system 600 may include a processing device 602, a volatile memory 604 (e.g., Random Access Memory (RAM)), a non-volatile memory 606 (e.g., Read-Only Memory (ROM) or Electrically-Erasable Programmable ROM (EEPROM)), and a data storage device 618, which may communicate with each other via a bus 608.

Processing device 602 may be provided by one or more processors such as a general purpose processor (such as, for example, a Complex Instruction Set Computing (CISC) microprocessor, a Reduced Instruction Set Computing (RISC) microprocessor, a Very Long Instruction Word (VLIW) microprocessor, a microprocessor implementing other types of instruction sets, or a microprocessor implementing a combination of types of instruction sets) or a specialized processor (such as, for example, an Application Specific Integrated Circuit (ASIC), a Field Programmable Gate Array (FPGA), a Digital Signal Processor (DSP), or a network processor).

Computer system 600 may further include a network interface device 622 (e.g., coupled to network 674). Computer system 600 also may include a video display unit 610 (e.g., an LCD), an alphanumeric input device 612 (e.g., a keyboard), a cursor control device 614 (e.g., a mouse), and a signal generation device 620.

In some embodiments, data storage device 618 may include a non-transitory computer-readable storage medium 624 (e.g., non-transitory machine-readable medium, non-transitory machine-readable storage medium, or the like) on which may store instructions 626 encoding any one or more of the methods or functions described herein, including instructions encoding components of FIG. 1 (e.g., predictive component 114, control module 115, corrective action component 122, model 190, etc.) and for implementing methods described herein.

Instructions 626 may also reside, completely or partially, within volatile memory 604 and/or within processing device 602 during execution thereof by computer system 600, hence, volatile memory 604 and processing device 602 may also constitute machine-readable storage media.

While computer-readable storage medium 624 is shown in the illustrative examples as a single medium, the term “computer-readable storage medium” shall include a single medium or multiple media (e.g., a centralized or distributed database, and/or associated caches and servers) that store the one or more sets of executable instructions. The term “computer-readable storage medium” shall also include any tangible medium that is capable of storing or encoding a set of instructions for execution by a computer that cause the computer to perform any one or more of the methods described herein. The term “computer-readable storage medium” shall include, but not be limited to, solid-state memories, optical media, and magnetic media.

The methods, components, and features described herein may be implemented by discrete hardware components or may be integrated in the functionality of other hardware components such as ASICS, FPGAs, DSPs or similar devices. In addition, the methods, components, and features may be implemented by firmware modules or functional circuitry within hardware devices. Further, the methods, components, and features may be implemented in any combination of hardware devices and computer program components, or in computer programs.

Unless specifically stated otherwise, terms such as “receiving,” “performing,” “providing,” “obtaining,” “causing,” “accessing,” “determining,” “adding,” “using,” “training,” “reducing,” “generating,” “correcting,” or the like, refer to actions and processes performed or implemented by computer systems that manipulates and transforms data represented as physical (electronic) quantities within the computer system registers and memories into other data similarly represented as physical quantities within the computer system memories or registers or other such information storage, transmission or display devices. Also, the terms “first,” “second,” “third,” “fourth,” etc. as used herein are meant as labels to distinguish among different elements and may not have an ordinal meaning according to their numerical designation.

Examples described herein also relate to an apparatus for performing the methods described herein. This apparatus may be specially constructed for performing the methods described herein, or it may include a general purpose computer system selectively programmed by a computer program stored in the computer system. Such a computer program may be stored in a computer-readable tangible storage medium.

The methods and illustrative examples described herein are not inherently related to any particular computer or other apparatus. Various general purpose systems may be used in accordance with the teachings described herein, or it may prove convenient to construct more specialized apparatus to perform methods described herein and/or each of their individual functions, routines, subroutines, or operations. Examples of the structure for a variety of these systems are set forth in the description above.

The above description is intended to be illustrative, and not restrictive. Although the present disclosure has been described with references to specific illustrative examples and embodiments, it will be recognized that the present disclosure is not limited to the examples and embodiments described. The scope of the disclosure should be determined with reference to the following claims, along with the full scope of equivalents to which the claims are entitled.

What is claimed is:

1. A method comprising:
obtaining, by a run-to-run controller associated with a process chamber, first metrology data of a first substrate associated with a first processing operation by the process chamber, wherein the run-to-run controller comprises:
a first model configured to determine a relationship between substrate metrology and one or more process knob inputs, and
a second model comprising a constrained optimizer, configured to recommend one or more corrective actions based on the process knob inputs generated by the first model;
processing the first metrology data by the first model to determine a relationship between the metrology data of the first substrate and one or more process knobs of the first processing operation;
determining, by the second model, a recommended one or more process recipe updates based on the relationship between the first metrology data of the first substrate and the one or more process knobs of the first processing operation; and
updating a recipe associated with the first processing operation based on the recommended one or more process recipe updates.

2. The method of claim 1, wherein the first substrate comprises a substrate recently processed in accordance with the first processing operation, and wherein updating the recipe comprises adjusting recipe parameters for a subsequent substrate to be processed in accordance with an updated processing operation.

3. The method of claim 2, further comprising:
obtaining data indicative of disturbances present in processing operations of the subsequent substrate;
providing the data indicative of disturbances to a trained machine learning disturbance model;
obtaining output from the trained machine learning disturbance model based on the data indicative of disturbances; and
providing the output from the trained machine learning disturbance model to the run-to-run controller, wherein recommended one or more process recipe updates are further based on the output from the trained machine learning disturbance model.

4. The method of claim 3, wherein the disturbances comprise one or more of:
effects of upstream processing operations on the subsequent substrate;
equipment parameters of the process chamber; or
drift of the process chamber.

5. The method of claim 1, wherein the first substrate comprises a substrate to be processed in accordance with the first processing operation, and wherein the first metrology data of the first substrate comprises data indicative of performance of one or more upstream processing operations.

6. The method of claim 1, wherein the first model comprises a trained machine learning model or a physics-based model.

7. The method of claim 1, wherein the first metrology data of the first substrate comprises virtual metrology data, generated by a third model comprising a trained machine learning model configured to obtain data from on-board sensing associated with the process chamber, and to generate the virtual metrology data based on the data from on-board sensing.

8. The method of claim 1, further comprising:
obtaining second metrology data of a second substrate; and
processing the second metrology data by the first model, wherein the one or more process recipe updates are further based on output of the first model associated with the second metrology data.

9. The method of claim 1, wherein the first model further determines a level of certainty of the relationship between the metrology data of the first substrate and the one or more process knobs, and wherein determining the recommended one or more process recipe updates is further based on the level of certainty.

10. The method of claim 9, wherein the level of certainty is used by the second model to adjust one or more of:
prediction horizons;
control horizons;
weights of the optimizer; or
control response strength.

11. A method, comprising:
obtaining, by a run-to-run controller associated with a process chamber, first metrology data of a first substrate associated with a first processing operation of the process chamber, wherein the run-to-run controller comprises:
a first model configured to determine a relationship between substrate metrology and one or more process knob inputs, and
a second model comprising a constrained optimizer, configured to recommend adjustments to a process chamber digital twin feedback model based on the relationship determined by the first model;
providing output from the run-to-run controller based on the first metrology data of the first substrate to the process chamber digital twin feedback model, wherein the process chamber digital twin feedback model is configured to adjust operation of an associated process chamber based on sensor data of the process chamber; and
updating control parameters of the process chamber digital twin feedback model based on the output from the run-to-run controller.

12. The method of claim 11, further comprising providing a control signal to the process chamber based on the updated control parameters.

13. The method of claim 11, wherein the process chamber digital twin feedback model provides adjustments to the process chamber at a first frequency, and wherein the run-to-run controller provides output to the process chamber digital twin feedback model at a second frequency, less frequent than the first frequency.

14. The method of claim 11, wherein the first model comprises a trained machine learning model.

15. The method of claim 11, wherein the first metrology data comprises virtual metrology data generated by a trained machine learning model based on on-board sensing in association with a process tool including the process chamber.

16. A non-transitory machine-readable storage medium storing instructions which, when executed, cause a processing device to perform operations comprising:
obtaining, by a run-to-run controller associated with a process chamber, first metrology data of a first substrate associated with a first processing operation by the process chamber, wherein the run-to-run controller comprises:
a first model configured to determine a relationship between substrate metrology and one or more process knob inputs, and
a second model comprising a constrained optimizer, configured to recommend one or more corrective actions based on the process knob inputs generated by the first model;
processing the first metrology data by the first model to determine a relationship between the metrology data of the first substrate and one or more process knobs of the first processing operation;
determining, by the second model, a recommended one or more process recipe updates based on the relationship between the first metrology data of the first substrate and the one or more process knobs of the first processing operation; and
updating a recipe associated with the first processing operation based on the recommended one or more process recipe updates.

17. The non-transitory machine-readable storage medium of claim 16, wherein the first substrate comprises a substrate recently processed in accordance with the first processing operation, and wherein updating the recipe comprises adjusting recipe parameters for a subsequent substrate to be processed in accordance with an updated processing operation.

18. The non-transitory machine-readable storage medium of claim 16, wherein the first substrate comprises a substrate to be processed in accordance with the first processing operation, and wherein the first metrology data of the first substrate comprises data indicative of performance of one or more upstream processing operations.

19. The non-transitory machine-readable storage medium of claim 16, wherein the first metrology data of the first substrate comprises virtual metrology data, generated by a third model comprising a trained machine learning model configured to obtain data from on-board sensing in association with the process chamber, and generate the virtual metrology data based on the data from on-board sensing.

20. The non-transitory machine-readable storage medium of claim 16, wherein the first model further determines a level of certainty of the relationship between the metrology data of the first substrate and the one or more process knobs, and wherein determining the recommended one or more process recipe updates is further based on the level of certainty.
